(19) United States
(12) Patent Application Publication
(10) Pub. No.: US 2026/0136901 A1
(43) Pub. Date: May 14, 2026

(54) COPPER-BASED TUNNELING BARRIER LAYER FOR STRESS REDUCTION IN COPPER STRUCTURES AND METHODS FOR FORMING THE SAME

(71) Applicant: Taiwan Semiconductor Manufacturing Company Limited, Hsinchu (TW)

(72) Inventors: Yi-Chen LI, Taichung City (TW); Jen-Yuan CHANG, Hsinchu City (TW)

(21) Appl. No.: 18/942,991

(22) Filed: Nov. 11, 2024

(51) Int. Cl. H01L 21/768; C23C 8/04; C23C 8/12; C23C 8/24; C23C 8/36; H01L 23/532

(52) U.S. Cl. CPC H10W 20/055; C23C 8/04; C23C 8/12; C23C 8/24; C23C 8/36; H10W 20/033; H10W 20/056; H10W 20/081; H10W 20/425

(57) ABSTRACT

A device structure may be manufactured by forming a first copper-containing metal interconnect structure embedded in a first dielectric material layer; forming a second dielectric material layer over the first copper-containing metal interconnect structure and the first dielectric material layer; forming a cavity through the second dielectric material layer such that a surface segment of the first copper-containing metal interconnect structure is exposed underneath the cavity; converting a surface portion of the first copper-containing metal interconnect structure into a copper-based tunneling barrier layer; and forming a second copper-containing metal interconnect structure in the cavity on the copper-based tunneling barrier layer.

### BACKGROUND

In the field of semiconductor manufacturing, the reliability and performance of interconnect structures impact the overall integrity of electronic devices. A challenge arises in the context of copper-containing metal interconnect structures, which are prone to stress-related reliability issues, particularly delamination. This stress-related reliability issue stems from the mismatch in thermal expansion coefficients between copper and adjacent materials. The mismatch in thermal expansion coefficients may result in the buildup of tensile stress during thermal cycling. Such tensile stress buildup may result in defects such as hillocks and, ultimately, delamination, particularly in regions with large copper surfaces. Therefore, there is a need to mitigate these stress-induced issues to improve the yield and reliability of semiconductor devices, especially as package designs continue to evolve with increased density and complexity.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for the clarity of discussion.

FIG. 1 is a vertical cross-sectional view of an exemplary structure after formation of semiconductor devices and metal interconnect structures formed within dielectric material layers according to an embodiment of the present disclosure.

FIGS. 2A-2L are sequential vertical cross-sectional views of a region of the exemplary structure during formation of copper-containing metal interconnect structures and a copper-based tunneling barrier layer according to a first embodiment of the present disclosure.

FIGS. 3A-3D are sequential vertical cross-sectional views of a region of the exemplary structure during formation of copper-containing metal interconnect structures and a copper-based tunneling barrier layer according to a second embodiment of the present disclosure.

FIGS. 4A-4F are sequential vertical cross-sectional views of a region of the exemplary structure during formation of copper-containing metal interconnect structures and a copper-based tunneling barrier layer according to a third embodiment of the present disclosure.

FIGS. 5A and 5B are sequential vertical cross-sectional views of a region of the exemplary structure during formation of copper-containing metal interconnect structures and a copper-based tunneling barrier layer according to a fourth embodiment of the present disclosure.

FIGS. 6A and 6B are sequential vertical cross-sectional views of a region of the exemplary structure during formation of copper-containing metal interconnect structures and a copper-based tunneling barrier layer according to a fifth embodiment of the present disclosure.

FIGS. 7A and 7B are sequential vertical cross-sectional views of a region of the exemplary structure during formation of copper-containing metal interconnect structures and copper-based tunneling barrier layers according to a sixth embodiment of the present disclosure.

FIGS. 8A and 8B are sequential vertical cross-sectional views of a region of the exemplary structure during formation of copper-containing metal interconnect structures and copper-based tunneling barrier layers according to a seventh embodiment of the present disclosure.

FIGS. 9A and 9B are sequential vertical cross-sectional views of a region of the exemplary structure during formation of copper-containing metal interconnect structures and copper-based tunneling barrier layers according to an eighth embodiment of the present disclosure.

FIGS. 10A-10H are vertical cross-sectional views of a region of the exemplary structure according to additional embodiments of the present disclosure.

FIG. 11 is a vertical cross-sectional view of the exemplary structure after formation of the bonding pads.

FIG. 12A is a vertical cross-sectional view of a region of a reconstituted wafer around a first semiconductor die according to an embodiment of the present disclosure.

FIG. 12B is a top-down view of the in-process reconstituted wafer.

FIG. 13 is a vertical cross-sectional view of a region of the reconstituted wafer after formation of a first molding compound matrix according to an embodiment of the present disclosure.

FIG. 14 is a vertical cross-sectional view of a region of the reconstituted wafer after formation of a first bonding-level dielectric layer and first active bonding pads according to an embodiment of the present disclosure.

FIG. 15 is a vertical cross-sectional view of a region of the reconstituted wafer after attaching a second semiconductor die to each first semiconductor die according to an embodiment of the present disclosure.

FIG. 16A is a vertical cross-sectional view of a region of the reconstituted wafer after formation of a second molding compound matrix according to an embodiment of the present disclosure.

FIG. 16B is a top-down view of the region of the reconstituted wafer of FIG. 16A.

FIG. 17 is a first flowchart illustrating steps for forming a device structure according to an embodiment of the present disclosure.

FIG. 18 is a second flowchart illustrating steps for forming a device structure according to an embodiment of the present disclosure.

### DETAILED DESCRIPTION

The following disclosure provides many different embodiments, or examples, for implementing various features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All features of an original embodiment are presumed to be present in any derived embodiment unless expressly disclosed otherwise. Thus, features described with reference to related embodiments in the drawings and/or in the specification provide support for features in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features selected from elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Embodiments of the present disclosure address a challenge in semiconductor manufacturing, specifically concerning the reliability and performance of copper-containing metal interconnect structures. Copper-based interconnects are susceptible to stress-induced issues such as hillocks and delamination, particularly after thermal cycling. These issues result from a mismatch in thermal expansion coefficients between copper and adjacent dielectric materials, leading to the buildup of tensile stress. A copper-based tunneling barrier layer may be used to mitigate these stress-related reliability issues. The copper-based tunneling barrier layer may improve the integrity and performance of interconnects in semiconductor devices.

The copper-based tunneling barrier layer may be formed on the surface of a copper-containing metal interconnect structure, creating a thin dielectric layer composed of materials such as copper oxide, copper nitride, or copper oxynitride. This layer may be carefully engineered to be thin enough (typically in the range of 0.5 nm to 2.0 nm) to allow electron tunneling between the first and second copper-containing metal interconnect structures. By allowing tunneling, the barrier layer maintains electrical connectivity, which impacts device functionality, while also serving as a physical buffer that redistributes and mitigates the tensile stress that builds up during thermal cycling.

The mechanism by which the tunneling barrier layer reduces stress relates to the tunneling barrier layer's ability to accommodate differences in thermal expansion between the copper and the surrounding dielectric material. By providing a transitional layer that partially absorbs and redistributes the stress, the tunneling barrier layer prevents the concentration of stress at the interface, which would otherwise lead to defects such as hillocks and delamination. The presence of the tunneling barrier layer thus stabilizes the structure during temperature changes, reducing the likelihood of stress-induced failures.

The advantage of embodiments of the present disclosure lies in the ability to address stress-related reliability issues in copper interconnects without altering the manufacturing process or increasing costs. The methods for forming the tunneling barrier layer utilize established thermal and plasma treatments, ensuring compatibility with existing semiconductor fabrication processes. Furthermore, the flexibility in choosing the composition and thickness of the barrier layer allows for optimization based on specific device requirements. This approach not only enhances the reliability of the interconnect structures but also supports the use of metals such as copper in increasingly dense and complex semiconductor designs, thereby extending the applicability and performance of interconnect technology in advanced electronic devices. The various aspects of the present disclosure are now described with reference to accompanying drawings.

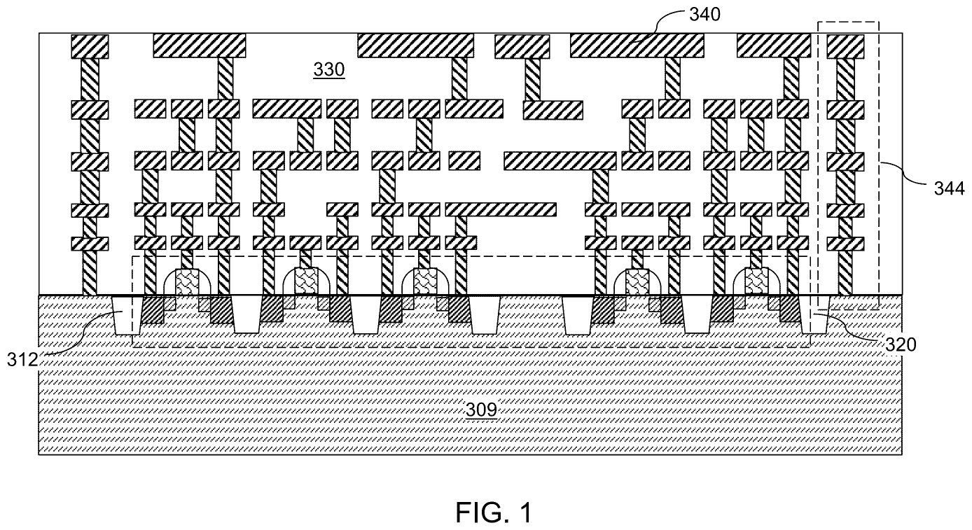

Referring to FIG. 1, an exemplary structure is illustrated, which may comprise semiconductor devices 320 formed on a semiconductor substrate 309, and metal interconnect structures 340 formed within interconnect-level dielectric material layers 330 and overlying the semiconductor devices 320. The semiconductor devices 320 may comprise field effect transistors, junction transistors, resistors, capacitors, inductors, diodes, and/or other semiconductor devices known in the art. In one embodiment, the semiconductor devices 320 may comprise complementary metal oxide semiconductor (CMOS) devices known in the art. The various semiconductor devices 320 may be electrically isolated from one another by shallow trench isolation structures 312.

The interconnect-level dielectric material layers 330 may comprise, and/or may consist of, inorganic dielectric materials such as silicate glass materials, silicon nitride, silicon carbide nitride, silicon oxynitride, and/or dielectric metal oxide materials. The metal interconnect structures 340 may comprise metal line structures, metal via structures, and/or metal pads. A subset of the metal interconnect structures 340 may laterally surround the semiconductor devices 320 and the rest of the metal interconnect structures 340 as a continuous wall structure, and may constitute an edge seal ring structure 344. In one embodiment, via-level metal interconnect structures and line-level metal interconnect structures may vertically alternate along the vertical direction. The total number of metal line levels within the metal interconnect structures 340 may be in a range from 1 to 20, such as from 2 to 10.

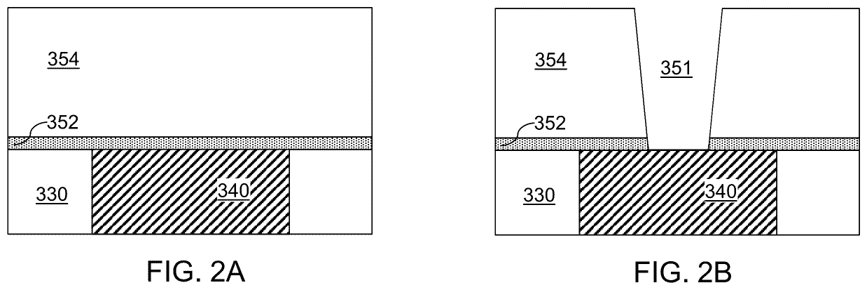

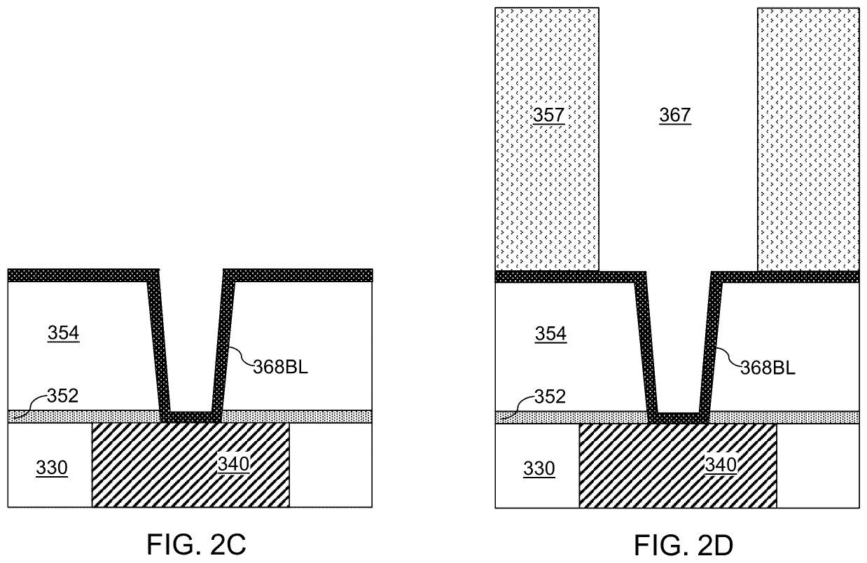

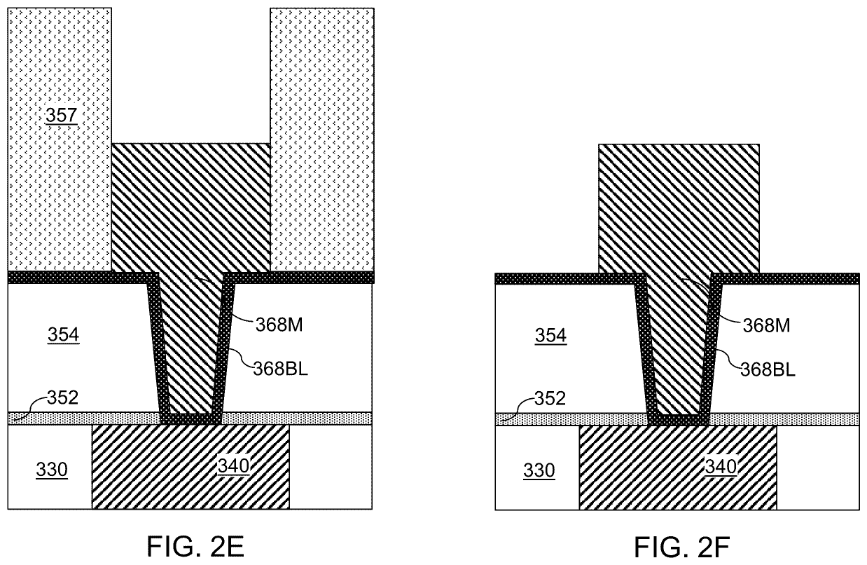

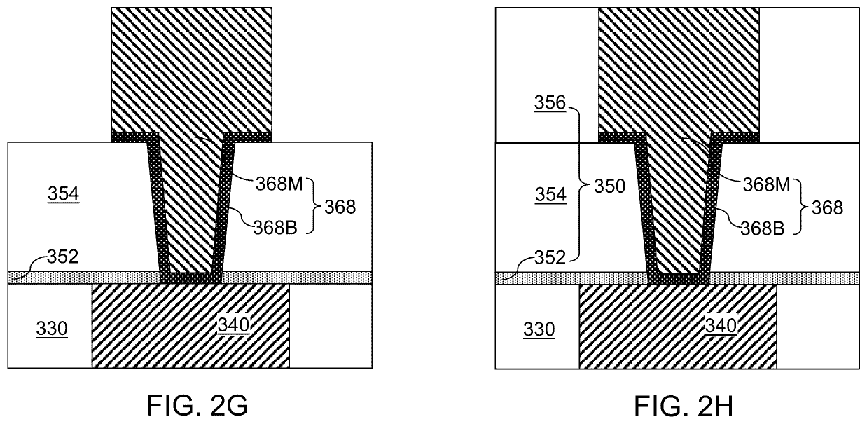

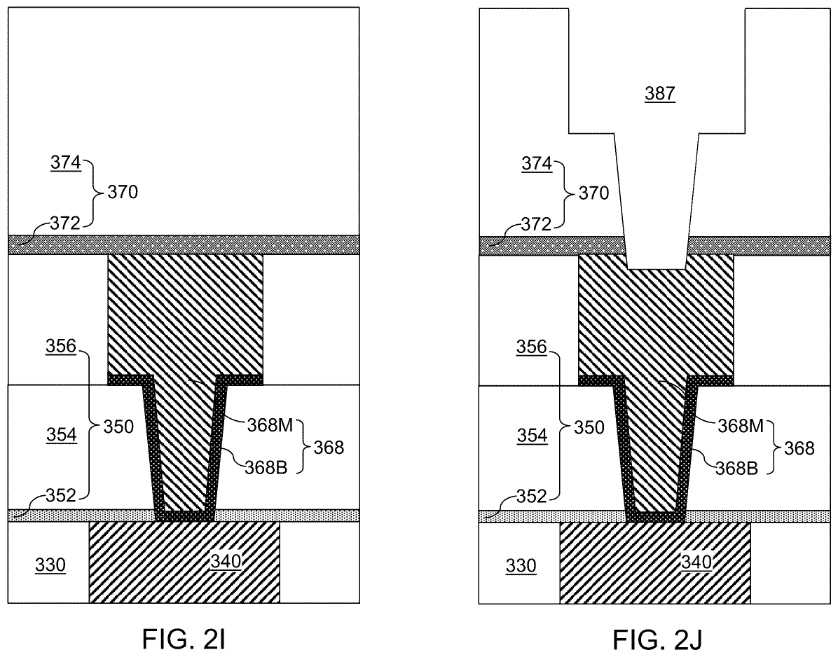

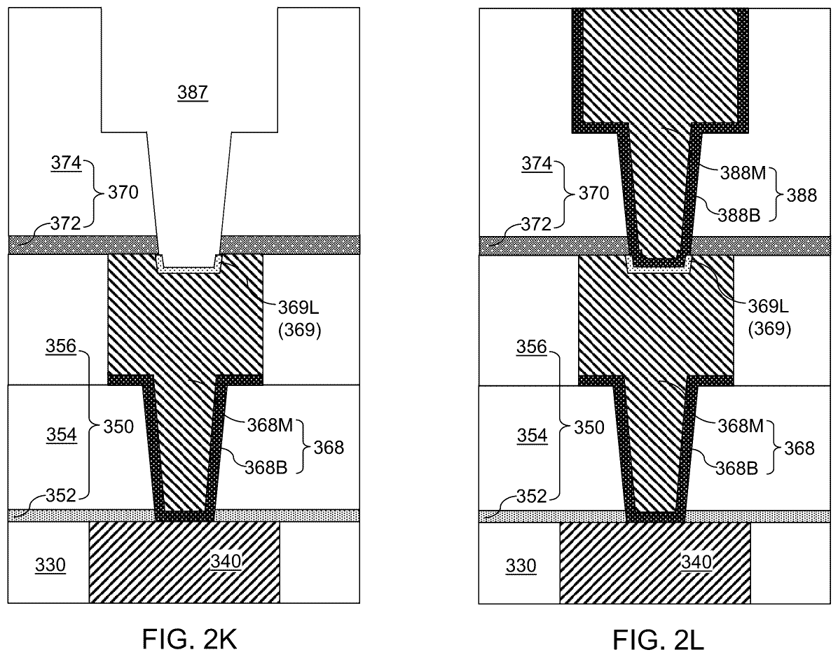

FIGS. 2A-2L are sequential vertical cross-sectional views of a region of the exemplary structure during formation of copper-containing metal interconnect structures (368, 388) and a copper-based tunneling barrier layer 369 according to a first embodiment of the present disclosure.

Referring to FIG. 2A, an optional first capping passivation layer 352 and a first via-level dielectric layer 354 may be formed over the interconnect-level dielectric material layers 330. The first capping passivation layer 352 comprises at least one diffusion-blocking dielectric material such as silicon nitride, silicon oxynitride, or silicon carbide nitride. The first capping passivation layer 352 may be formed by chemical vapor deposition (CVD), and may have a thickness in a range from 3 nm to 30 nm, although lesser and greater thicknesses may also be used. The first via-level dielectric layer 354 comprises an interlayer dielectric (ILD) material such as a silicate glass material. The thickness of the first via-level dielectric layer 354 may be in a range from 100 nm to 2,000 nm, such as from 200 nm to 1,000 nm, although lesser and greater thicknesses may also be used.

Referring to FIG. 2B, a photoresist layer (not shown) may be applied over the first via-level dielectric layer 354, and may be lithographically patterned to form openings over a subset of the metal interconnect structures 340 that may be located at a topmost level of the interconnect-level dielectric material layers 330. Each opening in the photoresist layer may be formed over a respective one of the metal interconnect structures 340 that is located at the topmost level of the interconnect-level dielectric material layers 330. An anisotropic etch process may be performed to transfer the pattern of the openings in the photoresist layer through the first via-level dielectric layer 354 and the first capping passivation layer 352. Via cavities 351 may be formed through the first via-level dielectric layer 354 and the first capping passivation layer 352 such that a top surface of an underlying metal interconnect structure 340 is physically exposed underneath each via cavity 351.

Referring to FIG. 2C, a first metallic barrier liner layer 368BL may be deposited over the first via-level dielectric layer 354 and in peripheral regions of the via cavities 351. The first metallic barrier liner layer 368BL functions as a conductive base layer that facilitates subsequent electroplating of copper by providing a uniform, conductive surface on which copper may be electroplated. The first metallic barrier liner layer 368BL may be deposited by physical vapor deposition (PVD), which may provide high conformity and thickness uniformity across the varied topography of the first via-level dielectric layer 354. In one embodiment, the first metallic barrier liner layer 368BL may comprise a layer stack including a metallic barrier material layer, such as tantalum or tantalum nitride (Ta/TaN), and an overlying copper layer. The first metallic barrier liner layer 368BL comprises a horizontally-extending portion that overlies the horizontal top surface of the first via-level dielectric layer 354 and vertically-extending portions that protrude downward from the horizontally-extending portion into a peripheral region of a respective one of the via cavities 351. The thickness of the first metallic barrier liner layer 368BL may be in a range from 30 nm to 200 nm, although lesser and greater thicknesses may also be used.

Referring to FIG. 2D, a patterned electroplating mask layer 357 may be formed over the first metallic barrier liner layer 368BL. In one embodiment, the patterned electroplating mask layer 357 may be formed by applying a photoresist layer over the first metallic barrier liner layer 368BL, and by lithographically patterning the photoresist layer to form discrete openings 367 therein. Each of the discrete openings 367 in the patterned electroplating mask layer 357 may have a greater area than a respective underlying via cavity 351 (shown in FIG. 2B). The lateral dimension of each discrete opening 367 in the patterned electroplating mask layer 357 may be in a range from 1 micron to 100 microns, although lesser and greater lateral dimensions may also be used.

Referring to FIG. 2E, an electroplating process may be performed to electroplate a metallic material, which may be any electroplatable material known in the art. In one embodiment, the electroplated metallic material may consist essentially of copper. The electroplated metallic material forms first electroplated material portions 368M. The first electroplated material portions 368M are formed in areas that are not masked by the patterned electroplating mask layer 357. In one embodiment, the first electroplated material portions 368M may consist essentially of copper. The height of the top surfaces of the first electroplated material portions 368M, as measured from the horizontal plane including the topmost surface of the first metallic barrier liner layer 368BL, may be in a range from 150 nm to 6,000 nm, such as from 300 nm to 3,000 nm, although lesser and greater heights may also be used.

Referring to FIG. 2F, the patterned electroplating mask layer 357 may be removed by ashing or by dissolution in a solvent.

Referring to FIG. 2G, unmasked portions of the first metallic barrier liner layer 368BL may be removed by performing an etch process that etches the material of the first metallic barrier liner layer 368BL selectively to the material of the first via-level dielectric layer 354. In instances in which the first metallic barrier liner layer 368BL comprises a layer stack of a metallic barrier liner layer composed of TiN or TaN and a copper seed layer, unmasked portions of the copper seed layer and the metallic barrier liner layer may be removed by performing a two-step etch process. First, an isotropic wet etching process using a persulfate-based solution, such as ammonium persulfate, may be used to selectively remove the copper seed layer without etching the material of the metallic barrier liner layer. Subsequently, a selective dry etch process, such as reactive ion etching (RIE) using fluorine-based chemistries (e.g., CF4 or SF6), may be performed to remove unmasked portions of the metallic barrier liner layer. A suitable clean process may be subsequently performed to remove any residual material. The first metallic barrier liner layer 368BL is divided into a plurality of first metallic barrier liners 368B. Each contiguous combination of a first metallic barrier liner 368B and a first electroplated material portion 368M comprises a first copper-containing metal interconnect structure 368.

Referring to FIG. 2H, an interlayer dielectric (ILD) material may be deposited over the first copper-containing metal interconnect structures 368 and the first via-level dielectric layer 354. A planarization process such as a chemical mechanical polishing process may be performed to remove the portion of the ILD material from above the horizontal plane including the top surfaces of the first copper-containing metal interconnect structures 368. The remaining portion of the ILD material constitutes a first line-level dielectric layer 356. The combination of the optional first capping passivation layer 352, the first via-level dielectric layer 354, and the first line-level dielectric layer 356 is herein referred to as a first dielectric material layer 350. First copper-containing metal interconnect structures 368 embedded in the first dielectric material layer 350 may be formed.

Referring to FIG. 2I, an optional second capping passivation layer 372 and a second interconnect-level dielectric layer 374 may be formed over the first dielectric material layer 350. The optional second capping passivation layer 372 and the second interconnect-level dielectric layer 374 are herein collectively referred to as a second dielectric material layer 370. The second capping passivation layer 372 comprises at least one diffusion-blocking dielectric material such as silicon nitride, silicon oxynitride, or silicon carbide nitride. The second capping passivation layer 372 may be formed by chemical vapor deposition, and may have a thickness in a range from 3 nm to 30 nm, although lesser and greater thicknesses may also be used. The second interconnect-level dielectric layer 374 comprises an interlayer dielectric (ILD) material such as a silicate glass material. The thickness of the second interconnect-level dielectric layer 374 may be in a range from 200 nm to 6,000 nm, such as from 400 nm to 3,000 nm, although lesser and greater thicknesses may also be used. In an alternative embodiment, a single dielectric material layer may be formed instead of a combination of a first via-level dielectric layer 354, an optional second capping passivation layer 372, and a second interconnect-level dielectric layer 374.

Referring to FIG. 2J, cavities 387 may be formed through the second dielectric material layer 370. For example, at least one patterned photoresist layer (not shown) may be formed over the second dielectric material layer 370, and each pattern in the at least one patterned photoresist layer may be transferred through the second dielectric material layer 370 by performing at least one anisotropic etch process. Generally, cavities 387 may be formed through at least one additional dielectric material layer such that a surface segment of a first copper-containing metal interconnect structure 368 or a copper-based tunneling barrier layer 369 is exposed underneath each of the cavities 387. In one embodiment, the cavities 387 may comprise integrated pad-and-via cavities. In this embodiment, each cavity 387 may comprise a via cavity portion located in a lower portion of the second dielectric material layer 370, and a pad cavity portion located in an upper portion of the second dielectric material layer 370.

The cavities 387 may be formed through the second dielectric material layer 370 such that a surface segment of the first copper-containing metal interconnect structure 368 is exposed underneath each cavity 387. In one embodiment, a portion of a top surface of the first copper-containing metal interconnect structure 368 may be vertically recessed during formation of the cavities 387. In one embodiment, physically exposed surfaces of a first copper-containing metal interconnect structure 368 may comprise a recessed surface segment of the first copper-containing metal interconnect structure 368 and at least one sidewall surface segment of the first copper-containing metal interconnect structure 368. In one embodiment, a periphery of the recessed surface segment coincides with a bottom periphery of the at least one sidewall surface segment. In one embodiment, the vertical recess distance of the recessed surface segment of the first copper-containing metal interconnect structure 368 relative to the topmost surface segment of the first copper-containing metal interconnect structure 368 may be in a range from 1 nm to 60 nm, such as from 3 nm to 20 nm, although lesser and greater vertical recess distances may also be used.

Referring to FIG. 2K, a physically exposed surface portion of each first copper-containing metal interconnect structure 368 may be converted into a copper-based tunneling barrier layer 369. Each such copper-based tunneling barrier layer 369 is formed on a surface segment of a top surface of a respective copper-containing metal interconnect structure 368 as a localized film, and is herein referred to as a localized copper-based tunneling barrier layer 369L. Generally, each copper-based tunneling barrier layer 369 may be formed by exposing the surface portion of the first copper-containing metal interconnect structure 368 to a gas-phase ambient including an oxidizer gas or a nitridation agent gas at a temperature in a range from 10 degrees Celsius to 450 degrees Celsius. In one embodiment, the gas-phase ambient may comprise at least one of ammonia gas, oxygen gas, ozone gas, nitrous oxide (N₂O) gas, nitric oxide (NO) gas, and nitrogen dioxide (NO₂) gas.

In one embodiment, the copper-based tunneling barrier layers 369 may be formed by performing at least one of a thermal oxidation process and a thermal nitridation process. In this embodiment, the elevated temperature of the thermal oxidation process may be in a range from 200 degrees Celsius to 450 degrees Celsius, and preferably in a range from 250 degrees Celsius to 400 degrees Celsius. Additionally or alternatively, the copper-based tunneling barrier layers 369 may be formed by performing at least one of a plasma oxidation process and a plasma nitridation process. In one embodiment, the copper-based tunneling barrier layers 369 may comprise a dielectric material selected from copper oxide, copper nitride, or copper oxynitride.

According to an aspect of the present disclosure, each copper-based tunneling barrier layer 369 has a thickness that provides charge tunneling when an electrical bias voltage greater than 0.5 V is applied thereacross. In one embodiment, each copper-based tunneling barrier layer 369 may have a thickness in a range from 0.5 nm to 2.0 nm.

Generally, each copper-based tunneling barrier layer 369 may be formed by performing at least one of a surface oxidation process and a surface nitridation process. The copper-based tunneling barrier layer 369 is formed on a surface segment of a top surface of a respective first copper-containing metal interconnect structure 368 that is less than the entirety of the top surface of the respective first copper-containing metal interconnect structure 368.

In one embodiment, the copper-based tunneling barrier layer 369 may be formed by a combination of an oxidation process and a nitridation process such that a nitrogen concentration gradient and an oxygen concentration gradient is present in the copper-based tunneling barrier layer 369. In this embodiment, the oxidation process may precede, or follow, the nitridation process. In one embodiment, the copper-based tunneling barrier layer 369 may comprise an inhomogeneous copper oxynitride material such that a nitrogen concentration gradient and an oxygen concentration gradient is present in the copper-based tunneling barrier layer 369. The atomic concentration of oxygen atoms may increase, or decrease, along a vertical direction in a horizontally-extending portion of the copper-based tunneling barrier layer 369. Likewise, the atomic concentration of oxygen atoms may decrease, or increase, along a vertical direction in a horizontally-extending portion of the copper-based tunneling barrier layer 369. In this embodiment, the atomic concentration of oxygen atoms and the atomic concentration of nitrogen atoms may change in a complementary manner (i.e., in opposite directions).

Referring to FIG. 2L, a second metallic barrier liner layer may be deposited over the second dielectric material layer 370 and in peripheral regions of the cavities 387. The second metallic barrier liner layer functions as a conductive base layer that facilitates subsequent electroplating of copper by providing a uniform, conductive surface on which copper may be electroplated. The second metallic barrier liner layer may be deposited by physical vapor deposition (PVD), which may provide high conformity and thickness uniformity across the varied topography of the second dielectric material layer 370. In one embodiment, the second metallic barrier liner layer may comprise a layer stack including a metallic barrier material layer, such as tantalum or tantalum nitride (Ta/TaN), and an overlying copper layer. The second metallic barrier liner layer comprises a horizontally-extending portion that overlies the horizontal top surface of the second dielectric material layer 370 and vertically-extending portions that protrude downward from the horizontally-extending portion into a peripheral region of a respective one of the cavities 387. The thickness of the second metallic barrier liner layer may be in a range from 30 nm to 200 nm, although lesser and greater thicknesses may also be used.

An electroplating process may be performed to electroplate a metallic material, which may be any electroplatable material known in the art. In one embodiment, the electroplated metallic material may consist essentially of copper. A planarization process such as a chemical mechanical polishing process may be performed to remove portions of the electroplated metallic material and the second metallic barrier liner layer from above the horizontal plane including the top surface of the second dielectric material layer 370. Each remaining portion of the second metallic barrier liner layer comprises a second metallic barrier liner 388B. Each remaining portion of the electroplated metallic material comprises a second electroplated material portion 388M. Each contiguous combination of a second metallic barrier liner 388B and a second electroplated material portion 388M constitutes a second copper-containing metal interconnect structure 388.

In one embodiment, a horizontally-extending portion of a copper-based tunneling barrier layer 369 is interposed between a first copper-containing metal interconnect structure 368 and a second copper-containing metal interconnect structure 388. The second copper-containing metal interconnect structure 388 may be formed directly on the horizontally-extending portion of the copper-based tunneling barrier layer 369, and may be vertically spaced from the first copper-containing metal interconnect structure 368 by the horizontally-extending portion of the copper-based tunneling barrier layer 369. The copper-based tunneling barrier layer 369 may have a uniform thickness throughout.

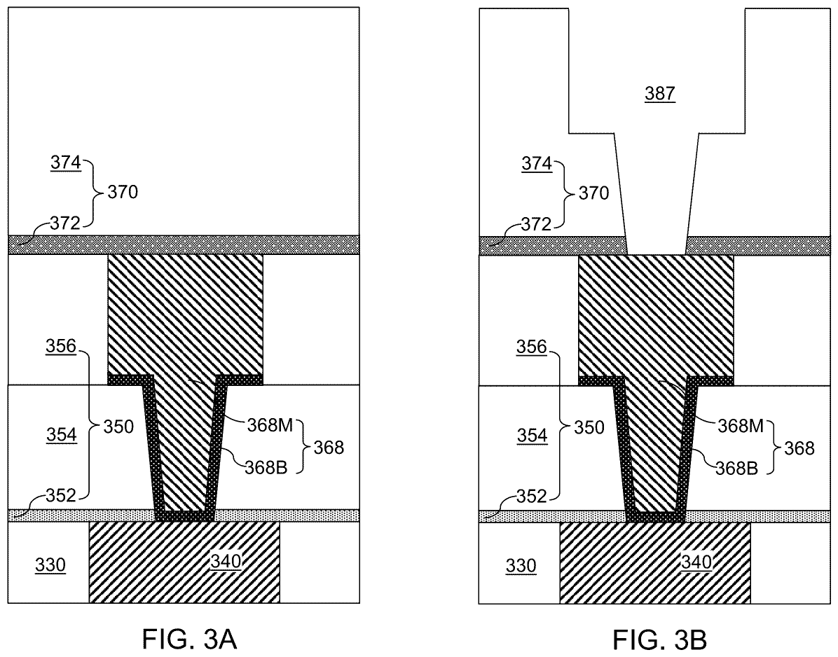

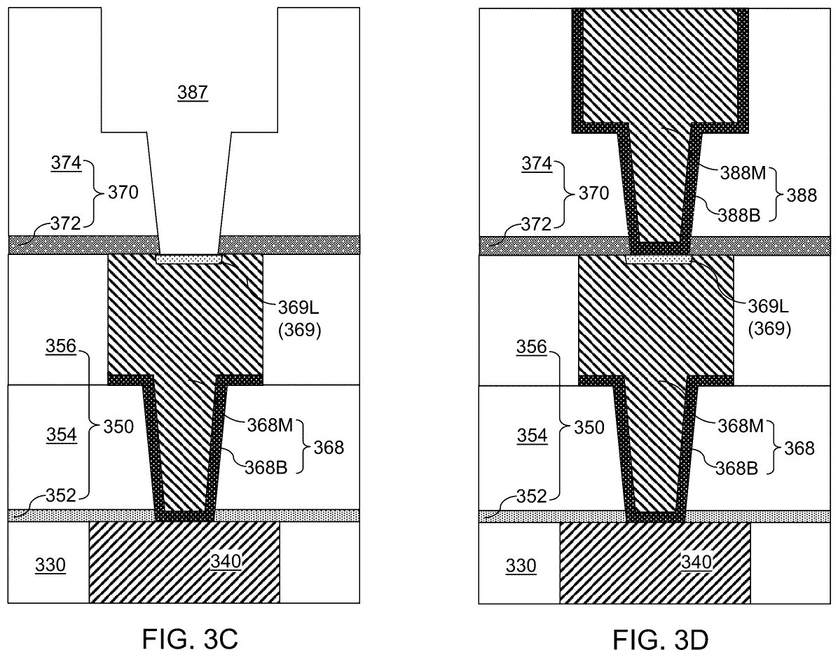

FIGS. 3A-3D are sequential vertical cross-sectional views of a region of the exemplary structure during formation of copper-containing metal interconnect structures (368, 388) and a copper-based tunneling barrier layer 369 according to a second embodiment of the present disclosure.

Referring to FIG. 3A, the exemplary structure according to the second embodiment of the present disclosure is illustrated after formation of the second dielectric material layer 370. The exemplary structure illustrated in FIG. 3A may be the same as the exemplary structure according to the first embodiment of the present disclosure as described with reference to FIG. 2I.

Referring to FIG. 3B, the processing steps described with reference to FIG. 2J may be performed with a modification in the anisotropic etch chemistry. Specifically, the anisotropic etch chemistry may be highly selective to the material of the first electroplated material portions 368M, which may be copper portions. In this embodiment, the cavities 387 may be formed through the second dielectric material layer 370 such that physically exposed surface segments of the first copper-containing metal interconnect structures 368 are not recessed. Thus, the physically exposed surface segments of the first copper-containing metal interconnect structures 368 may be coplanar with top surface segments of the first copper-containing metal interconnect structures 368 that are not physically exposed.

Referring to FIG. 3C, the processing steps described with reference to FIG. 2K may be performed to convert each physically exposed surface portion of the first copper-containing metal interconnect structures 368 into copper-based tunneling barrier layers 369. Each such copper-based tunneling barrier layer 369 may be formed on a surface segment of a top surface of a respective copper-containing metal interconnect structure 368 as a localized film, and is herein referred to as a localized copper-based tunneling barrier layer 369L. Any of the processing steps described with reference to FIG. 2K may be used to form the copper-based tunneling barrier layers 369, and as such, the copper-based tunneling barrier layers 369 may have any of the properties described with reference to FIG. 2K. Each copper-based tunneling barrier layer 369 may be formed on a surface segment of a top surface of a respective first copper-containing metal interconnect structure 368 that is less than the entirety of the top surface of the respective first copper-containing metal interconnect structure 368.

Referring to FIG. 3D, the processing steps described with reference to FIG. 2L may be performed to form a second copper-containing metal interconnect structure 388 in each cavity 387. Each copper-based tunneling barrier layer 369 may consist of a horizontally-extending portion. In one embodiment, a copper-based tunneling barrier layer 369 may be interposed between a first copper-containing metal interconnect structure 368 and a second copper-containing metal interconnect structure 388. The second copper-containing metal interconnect structure 388 may be formed directly on the copper-based tunneling barrier layer 369, and may be vertically spaced from the first copper-containing metal interconnect structure 368 by the copper-based tunneling barrier layer 369. The copper-based tunneling barrier layer 369 may have a uniform thickness throughout.

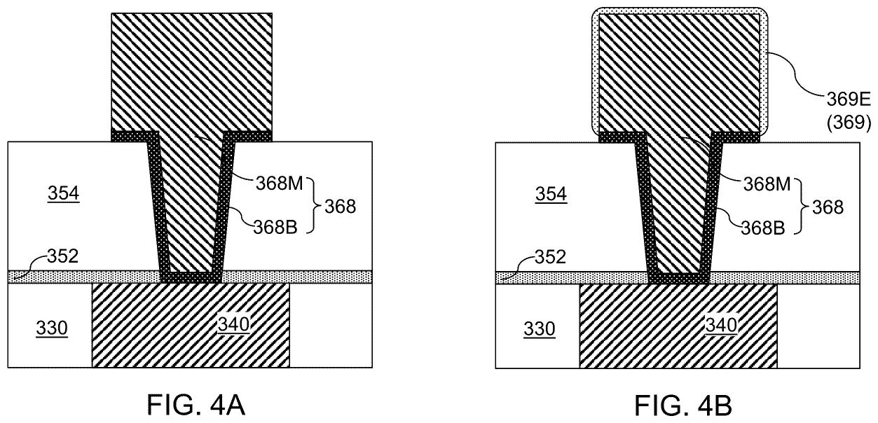

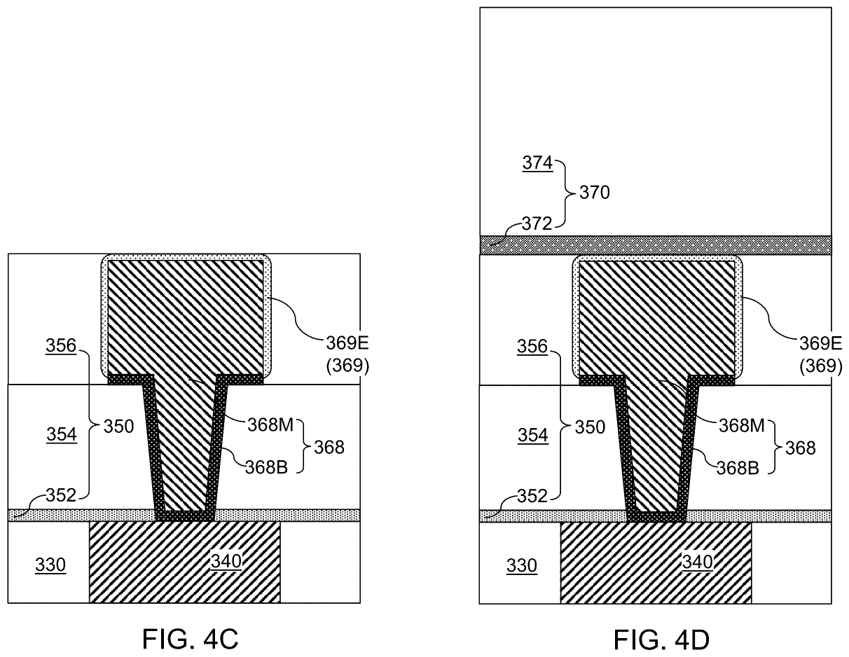

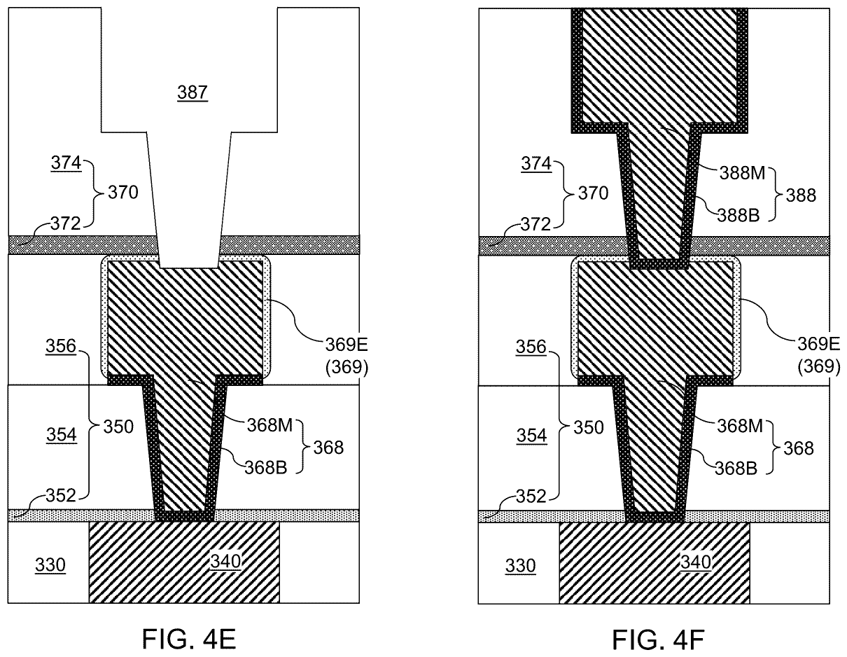

FIGS. 4A-4F are sequential vertical cross-sectional views of a region of the exemplary structure during formation of copper-containing metal interconnect structures (368, 388) and a copper-based tunneling barrier layer 369 according to a third embodiment of the present disclosure.

Referring to FIG. 4A, the exemplary structure according to the third embodiment of the present disclosure is illustrated after formation of the second dielectric material layer 370. The exemplary structure illustrated in FIG. 3A may be the same as the exemplary structure according to the first embodiment of the present disclosure as described with reference to FIG. 2G.

Referring to FIG. 4B, physically exposed surfaces of each first copper-containing metal interconnect structure 368 may be converted into a copper-based tunneling barrier layer 369. Each such copper-based tunneling barrier layer 369 may be a continuous material layer that encapsulates a respective one of the first copper-containing metal interconnect structures 368, and is herein referred to as an encapsulating copper-based tunneling barrier layer 369E. Each copper-based tunneling barrier layer 369 is formed on a top surface and at least one sidewall of a respective first copper-containing metal interconnect structure 368. In one embodiment, each encapsulating copper-based tunneling dielectric layer 369E contacts a top surface and each sidewall of a respective one of the first copper-containing metal interconnect structures 368. Generally, each copper-based tunneling barrier layer 369 may be formed by exposing the surface portion of the first copper-containing metal interconnect structure 368 to a gas-phase ambient including an oxidizer gas or a nitridation agent gas at a temperature in a range from 10 degrees Celsius to 450 degrees Celsius. In one embodiment, the gas-phase ambient may comprise at least one of ammonia gas, oxygen gas, ozone gas, nitrous oxide (N₂O) gas, nitric oxide (NO) gas, and nitrogen dioxide (NO₂) gas.

In one embodiment, the copper-based tunneling barrier layers 369 may be formed by performing at least one of a thermal oxidation process and a thermal nitridation process. In this embodiment, the elevated temperature of the thermal oxidation process may be in a range from 200 degrees Celsius to 450 degrees Celsius, and preferably in a range from 250 degrees Celsius to 400 degrees Celsius. Additionally or alternatively, the copper-based tunneling barrier layers 369 may be formed by performing at least one of a plasma oxidation process and a plasma nitridation process. In one embodiment, the copper-based tunneling barrier layers 369 may comprise a dielectric material selected from copper oxide, copper nitride, or copper oxynitride.

According to an aspect of the present disclosure, each copper-based tunneling barrier layer 369 has a thickness that provides charge tunneling when an electrical bias voltage greater than 0.5 V is applied thereacross. In one embodiment, each copper-based tunneling barrier layer 369 may have a thickness in a range from 0.5 nm to 2.0 nm.

Generally, each copper-based tunneling barrier layer 369 may be formed by performing at least one of a surface oxidation process and a surface nitridation process. The copper-based tunneling barrier layer 369 is formed on a surface segment of a top surface of a respective first copper-containing metal interconnect structure 368 that is less than the entirety of the top surface of the respective first copper-containing metal interconnect structure 368.

In one embodiment, the copper-based tunneling barrier layer 369 may be formed by a combination of an oxidation process and a nitridation process such that a nitrogen concentration gradient and an oxygen concentration gradient is present in the copper-based tunneling barrier layer 369. In this embodiment, the oxidation process may precede, or follow, the nitridation process. In one embodiment, the copper-based tunneling barrier layer 369 may comprise an inhomogeneous copper oxynitride material such that a nitrogen concentration gradient and an oxygen concentration gradient is present in the copper-based tunneling barrier layer 369. The atomic concentration of oxygen atoms may increase, or decrease, along a vertical direction in a horizontally-extending portion of the copper-based tunneling barrier layer 369. Likewise, the atomic concentration of oxygen atoms may decrease, or increase, along a vertical direction in a horizontally-extending portion of the copper-based tunneling barrier layer 369. In this embodiment, the atomic concentration of oxygen atoms and the atomic concentration of nitrogen atoms may change in a complementary manner (i.e., in opposite directions).

Referring to FIG. 4C, an interlayer dielectric (ILD) material may be deposited over the first copper-containing metal interconnect structures 368 and the first via-level dielectric layer 354. A planarization process such as a chemical mechanical polishing process may be performed to remove the portion of the ILD material from above the horizontal plane including the top surfaces of the copper-based tunneling barrier layers 369. In one embodiment, the thickness of the horizontally-extending portions of the copper-based tunneling barrier layers 369 overlying the first copper-containing metal interconnect structures 368 may be reduced during the planarization process. The remaining portion of the ILD material constitutes a first line-level dielectric layer 356. The combination of the optional first capping passivation layer 352, the first via-level dielectric layer 354, and the first line-level dielectric layer 356 is herein referred to as a first dielectric material layer 350. First copper-containing metal interconnect structures 368 embedded in the first dielectric material layer 350 may be formed.

Referring to FIG. 4D, an optional second capping passivation layer 372 and a second interconnect-level dielectric layer 374 may be formed over the first dielectric material layer 350. The optional second capping passivation layer 372 and the second interconnect-level dielectric layer 374 are herein collectively referred to a second dielectric material layer 370. The second capping passivation layer 372 comprises at least one diffusion-blocking dielectric material such as silicon nitride, silicon oxynitride, or silicon carbide nitride. The second capping passivation layer 372 may be formed by chemical vapor deposition, and may have a thickness in a range from 3 nm to 30 nm, although lesser and greater thicknesses may also be used. The second interconnect-level dielectric layer 374 comprises an interlayer dielectric (ILD) material such as a silicate glass material. The thickness of the second interconnect-level dielectric layer 374 may be in a range from 200 nm to 6,000 nm, such as from 400 nm to 3,000 nm, although lesser and greater thicknesses may also be used. In an alternative embodiment, a single dielectric material layer may be formed instead of a combination of a first via-level dielectric layer 354, an optional second capping passivation layer 372, and a second interconnect-level dielectric layer 374.

Referring to FIG. 4E, cavities 387 may be formed through the second dielectric material layer 370. For example, at least one patterned photoresist layer (not shown) may be formed over the second dielectric material layer 370, and each pattern in the at least one patterned photoresist layer may be transferred through the second dielectric material layer 370 by performing at least one anisotropic etch process. Generally, cavities 387 may be formed through at least one additional dielectric material layer such that a surface segment of a first copper-containing metal interconnect structure 368 or a copper-based tunneling barrier layer 369 is exposed underneath each of the cavities 387. In one embodiment, the cavities 387 may comprise integrated pad-and-via cavities. In this embodiment, each cavity 387 may comprise a via cavity portion located in a lower portion of the second dielectric material layer 370, and a pad cavity portion located in an upper portion of the second dielectric material layer 370.

The cavities 387 may be formed through the second dielectric material layer 370 such that a surface segment of the first copper-containing metal interconnect structure 368 is exposed underneath each cavity 387. In one embodiment, a portion of a top surface of the first copper-containing metal interconnect structure 368 may be vertically recessed during formation of the cavities 387. In one embodiment, physically exposed surfaces of a first copper-containing metal interconnect structure 368 may comprise a recessed surface segment of the first copper-containing metal interconnect structure 368 and at least one sidewall surface segment of the first copper-containing metal interconnect structure 368. In one embodiment, a periphery of the recessed surface segment coincides with a bottom periphery of the at least one sidewall surface segment. In one embodiment, the vertical recess distance of the recessed surface segment of the first copper-containing metal interconnect structure 368 relative to the topmost surface segment of the first copper-containing metal interconnect structure 368 may be in a range from 1 nm to 60 nm, such as from 3 nm to 20 nm, although lesser and greater vertical recess distances may also be used.

Referring to FIG. 4F, a second metallic barrier liner layer may be deposited over the second dielectric material layer 370 and in peripheral regions of the cavities 387. The second metallic barrier liner layer functions as a conductive base layer that facilitates subsequent electroplating of copper by providing a uniform, conductive surface on which copper may be electroplated. The second metallic barrier liner layer may be deposited by physical vapor deposition (PVD), which may provide high conformity and thickness uniformity across the varied topography of the second dielectric material layer 370. In one embodiment, the second metallic barrier liner layer may comprise a layer stack including a metallic barrier material layer, such as tantalum or tantalum nitride (Ta/TaN), and an overlying copper layer. The second metallic barrier liner layer comprises a horizontally-extending portion that overlies the horizontal top surface of the second dielectric material layer 370 and vertically-extending portions that protrude downward from the horizontally-extending portion into a peripheral region of a respective one of the cavities 387. The thickness of the second metallic barrier liner layer may be in a range from 30 nm to 200 nm, although lesser and greater thicknesses may also be used.

An electroplating process may be performed to electroplate a metallic material, which may be any electroplatable material known in the art. In one embodiment, the electroplated metallic material may consist essentially of copper. A planarization process such as a chemical mechanical polishing process may be performed to remove portions of the electroplated metallic material and the second metallic barrier liner layer from above the horizontal plane including the top surface of the second dielectric material layer 370. Each remaining portion of the second metallic barrier liner layer comprises a second metallic barrier liner 388B. Each remaining portion of the electroplated metallic material comprises a second electroplated material portion 388M. Each contiguous combination of a second metallic barrier liner 388B and a second electroplated material portion 388M constitutes a second copper-containing metal interconnect structure 388. The second copper-containing metal interconnect structure 388 may be formed directly on a recessed horizontal surface segment of the first copper-containing metal interconnect structure 368.

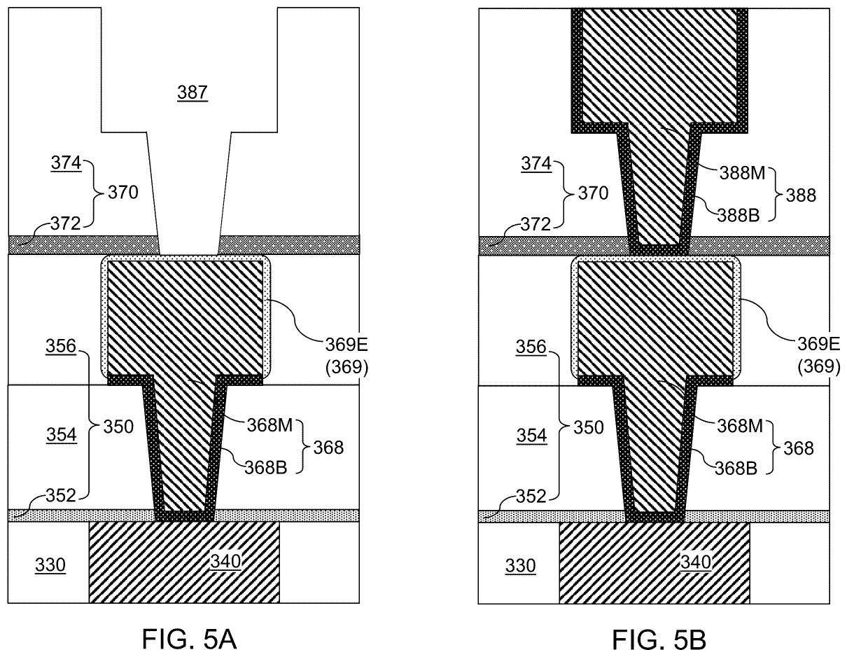

FIGS. 5A and 5B are sequential vertical cross-sectional views of a region of the exemplary structure during formation of copper-containing metal interconnect structures (368, 388) and a copper-based tunneling barrier layer 369 according to a fourth embodiment of the present disclosure.

Referring to FIG. 5A, a region of the exemplary structure is illustrated after formation of a second dielectric material layer 370 and cavities 387. The exemplary structure illustrated in FIG. 5A may be derived from the exemplary structure illustrated in FIG. 4E by modifying the chemistry of the anisotropic etch process that forms the cavities 387. Specifically, the anisotropic etch chemistry may be highly selective to the material of the copper-based tunneling barrier layer 369, which may comprise copper oxide, copper nitride, or copper oxynitride. In this embodiment, the cavities 387 may be formed through the second dielectric material layer 370 such that physically exposed surface segments of the copper-based tunneling barrier layer 369 are not recessed.

Referring to FIG. 5B, the processing steps described with reference to FIG. 2L may be performed to form a second copper-containing metal interconnect structure 388 in each cavity 387. In one embodiment, a copper-based tunneling barrier layer 369 is interposed between a first copper-containing metal interconnect structure 368 and a second copper-containing metal interconnect structure 388. The second copper-containing metal interconnect structure 388 may be formed directly on the copper-based tunneling barrier layer 369, and may be vertically spaced from the first copper-containing metal interconnect structure 368 by the copper-based tunneling barrier layer 369.

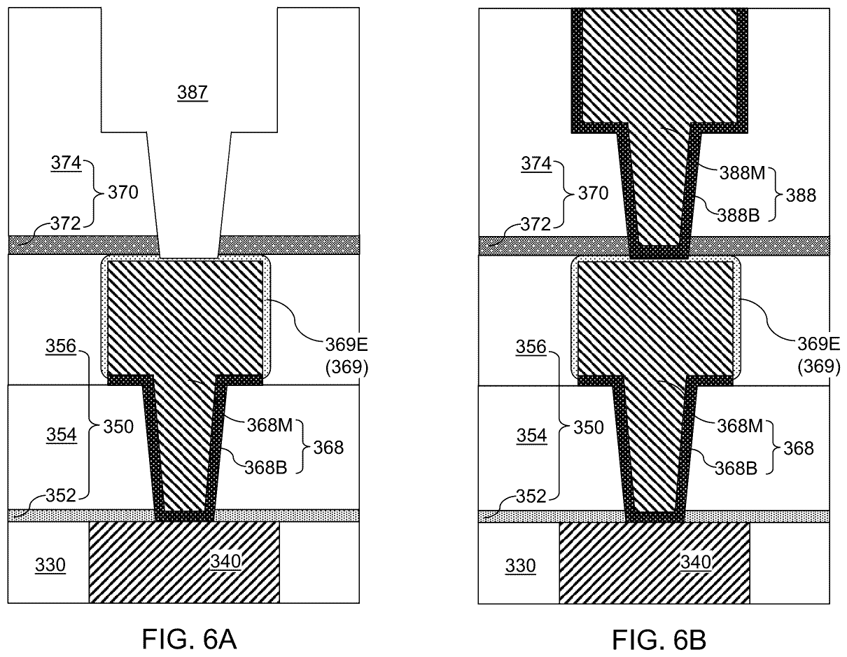

FIGS. 6A and 6B are sequential vertical cross-sectional views of a region of the exemplary structure during formation of copper-containing metal interconnect structures (368, 388) and a copper-based tunneling barrier layer 369 according to a fifth embodiment of the present disclosure.

Referring to FIG. 6A, a region of the exemplary structure is illustrated after formation of a second dielectric material layer 370 and cavities 387. The exemplary structure illustrated in FIG. 6A may be derived from the exemplary structure illustrated in FIG. 4E by modifying the chemistry of the anisotropic etch process that forms the cavities 387. Specifically, the anisotropic etch chemistry may be selective to the material of the copper-based tunneling barrier layer 369, which may comprise copper oxide, copper nitride, or copper oxynitride. A cavity 387 may extend through an upper portion of the copper-based tunneling barrier layer 369, but does not vertically extend through the entirety of the copper-based tunneling barrier layer 369. In this embodiment, the cavities 387 may be formed through the second dielectric material layer 370 such that physically exposed surface segments of the copper-based tunneling barrier layer 369 are recessed by a recess distance that is less than the thickness of the copper-based tunneling barrier layer 369.

Referring to FIG. 6B, the processing steps described with reference to FIG. 2L may be performed to form a second copper-containing metal interconnect structure 388 in each cavity 387. In one embodiment, a copper-based tunneling barrier layer 369 is interposed between a first copper-containing metal interconnect structure 368 and a second copper-containing metal interconnect structure 388. The second copper-containing metal interconnect structure 388 may be formed directly on a thinned portion of the copper-based tunneling barrier layer 369, and may be vertically spaced from the first copper-containing metal interconnect structure 368 by the thinned portion of the copper-based tunneling barrier layer 369. In one embodiment, a first portion of the copper-based tunneling barrier layer 369 that is interposed between the first copper-containing metal interconnect structure 368 and the second copper-containing metal interconnect structure 388 has a lesser thickness than a second portion of the copper-based tunneling barrier layer 369 that contacts the first copper-containing metal interconnect structure 368 and not contacting the second copper-containing metal interconnect structure 388.

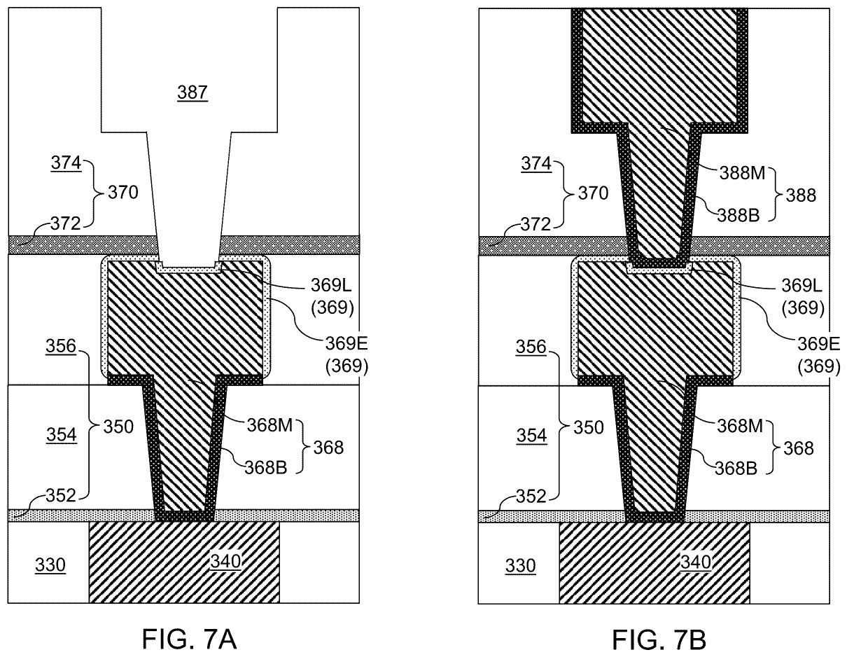

FIGS. 7A and 7B are sequential vertical cross-sectional views of a region of the exemplary structure during formation of copper-containing metal interconnect structures (368, 388) and copper-based tunneling barrier layers 369 according to a sixth embodiment of the present disclosure.

Referring to FIG. 7A, a region of the exemplary structure according to the sixth embodiment is illustrated after formation of an additional copper-based tunneling barrier layer 369. The exemplary structure illustrated in FIG. 7A may be derived from the exemplary structure illustrated in FIG. 4E by converting a physically exposed surface portion of each first copper-containing metal interconnect structure 368 into an additional copper-based tunneling barrier layer 369. Specifically, a proximal portion of each first copper-containing metal interconnect structure 368 underlying a respective cavity 387 may be converted into an additional copper-based tunneling barrier layer 369. Each such copper-based tunneling barrier layer 369 is formed on a surface segment of a top surface of a respective copper-containing metal interconnect structure 368 as a localized film, and is herein referred to as a localized copper-based tunneling barrier layer 369L. Generally, each localized copper-based tunneling barrier layer 369L may be formed by exposing the surface portion of the first copper-containing metal interconnect structure 368 to a gas-phase ambient including an oxidizer gas or a nitridation agent gas at a temperature in a range from 10 degrees Celsius to 450 degrees Celsius. In one embodiment, the gas-phase ambient may comprise at least one of ammonia gas, oxygen gas, ozone gas, nitrous oxide (N₂O) gas, nitric oxide (NO) gas, and nitrogen dioxide (NO₂) gas.

In one embodiment, the localized copper-based tunneling barrier layer 369L may be formed by performing at least one of a thermal oxidation process and a thermal nitridation process. In this embodiment, the elevated temperature of the thermal oxidation process may be in a range from 200 degrees Celsius to 450 degrees Celsius, and preferably in a range from 250 degrees Celsius to 400 degrees Celsius. Additionally or alternatively, the localized copper-based tunneling barrier layer 369L may be formed by performing at least one of a plasma oxidation process and a plasma nitridation process. In one embodiment, the localized copper-based tunneling barrier layer 369L may comprise a dielectric material selected from copper oxide, copper nitride, or copper oxynitride.

According to an aspect of the present disclosure, each localized copper-based tunneling barrier layer 369L has a thickness that provides charge tunneling when an electrical bias voltage greater than 0.5 V is applied thereacross. In one embodiment, each localized copper-based tunneling barrier layer 369L may have a thickness in a range from 0.5 nm to 2.0 nm.

Generally, each localized copper-based tunneling barrier layer 369L may be formed by performing at least one of a surface oxidation process and a surface nitridation process. The localized copper-based tunneling barrier layer 369L is formed on a surface segment of a top surface of a respective first copper-containing metal interconnect structure 368 that is less than the entirety of the top surface of the respective first copper-containing metal interconnect structure 368.

In one embodiment, the localized copper-based tunneling barrier layer 369L may be formed by a combination of an oxidation process and a nitridation process such that a nitrogen concentration gradient and an oxygen concentration gradient is present in the localized copper-based tunneling barrier layer 369L. In this embodiment, the oxidation process may precede, or follow, the nitridation process. In one embodiment, the localized copper-based tunneling barrier layer 369L may comprise an inhomogeneous copper oxynitride material such that a nitrogen concentration gradient and an oxygen concentration gradient is present in the localized copper-based tunneling barrier layer 369L. The atomic concentration of oxygen atoms may increase, or decrease, along a vertical direction in a horizontally-extending portion of the localized copper-based tunneling barrier layer 369L. Likewise, the atomic concentration of oxygen atoms may decrease, or increase, along a vertical direction in a horizontally-extending portion of the localized copper-based tunneling barrier layer 369L. In this embodiment, the atomic concentration of oxygen atoms and the atomic concentration of nitrogen atoms may change in a complementary manner (i.e., in opposite directions).

Referring to FIG. 7B, the processing steps described with reference to FIG. 2L may be performed to form a second copper-containing metal interconnect structure 388 in each cavity 387. In one embodiment, a localized copper-based tunneling barrier layer 369L is interposed between a first copper-containing metal interconnect structure 368 and a second copper-containing metal interconnect structure 388. The second copper-containing metal interconnect structure 388 may be formed directly on the localized copper-based tunneling barrier layer 369L, and may be vertically spaced from the first copper-containing metal interconnect structure 368 by the localized copper-based tunneling barrier layer 369L. In one embodiment, each localized copper-based tunneling barrier layer 369L may be in contact with a top surface and a sidewall of a first copper-containing metal interconnect structure 368.

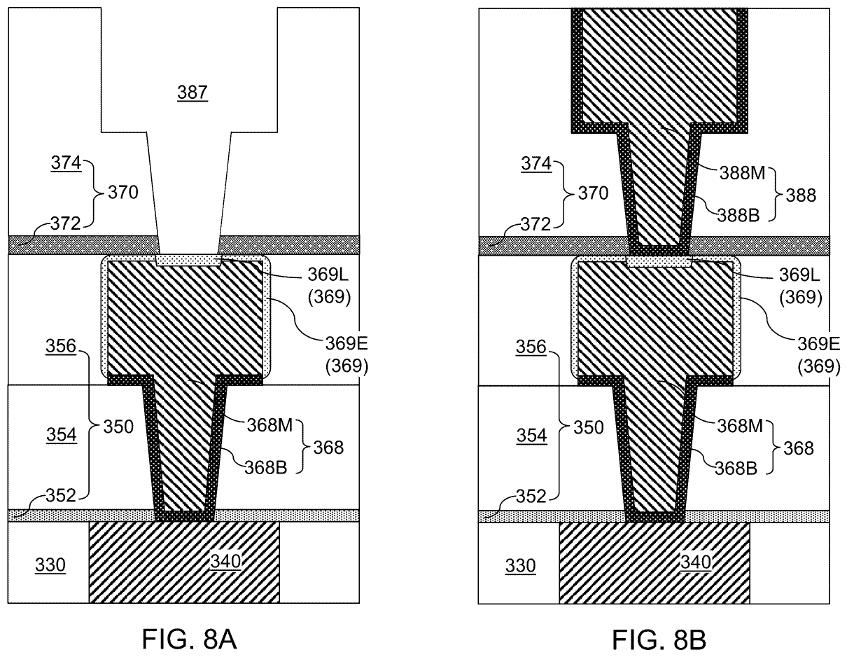

FIGS. 8A and 8B are sequential vertical cross-sectional views of a region of the exemplary structure during formation of copper-containing metal interconnect structures (368, 388) and copper-based tunneling barrier layers 369 according to a seventh embodiment of the present disclosure.

Referring to FIG. 8A, a region of the exemplary structure according to the seventh embodiment is illustrated after formation of an additional copper-based tunneling barrier layer 369. The exemplary structure illustrated in FIG. 8A may be derived from the exemplary structure illustrated in FIG. 5A by converting a surface portion of each first copper-containing metal interconnect structure 368 that underlies a respective cavity 387 and a horizontally-extending portion of the encapsulating copper-based tunneling barrier layer 369E into an additional copper-based tunneling barrier layer 369. The surface portion of each first copper-containing metal interconnect structure 368 is converted into a copper-based dielectric material (such as copper oxide, copper nitride, or copper oxynitride), and incorporates an overlying portion of the encapsulating copper-based tunneling barrier layer 369E to become a localized copper-based tunneling barrier layer 369L. In one embodiment, the localized copper-based tunneling barrier layer 369L has a thickness that is greater than the thickness of the encapsulating copper-based tunneling barrier layer 369E.

In one embodiment, the localized copper-based tunneling barrier layer 369L may have a different material composition than the encapsulating copper-based tunneling barrier layer 369E. In one embodiment, the encapsulating copper-based tunneling barrier layer 369E may be formed by performing an oxidation process and may comprise copper oxide, and the localized copper-based tunneling barrier layer 369L may be formed by performing a nitridation process and may comprise copper nitride or copper oxynitride. In another embodiment, the encapsulating copper-based tunneling barrier layer 369E may be formed by performing a nitridation process and may comprise copper nitride, and the localized copper-based tunneling barrier layer 369L may be formed by performing an oxidation process and may comprise copper oxide or copper oxynitride.

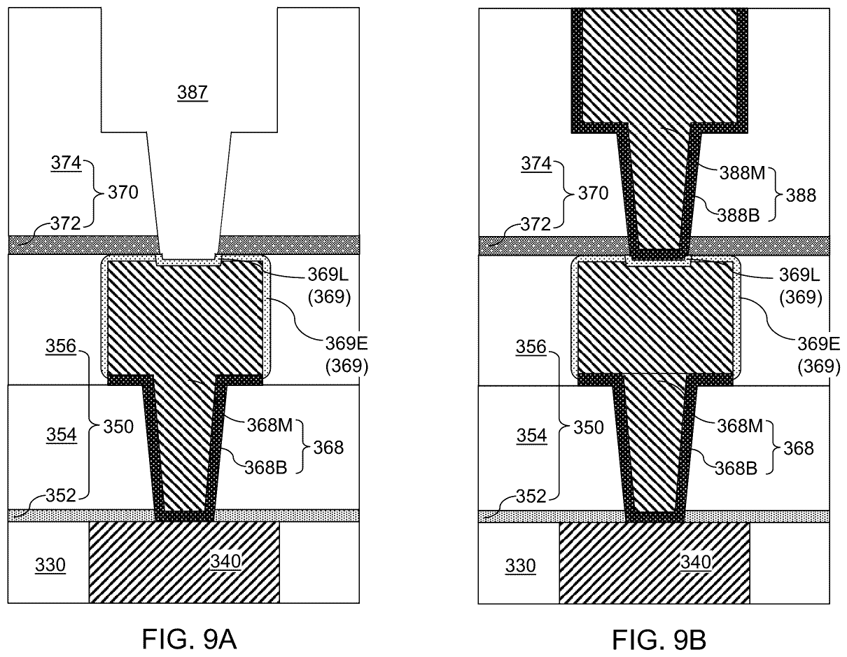

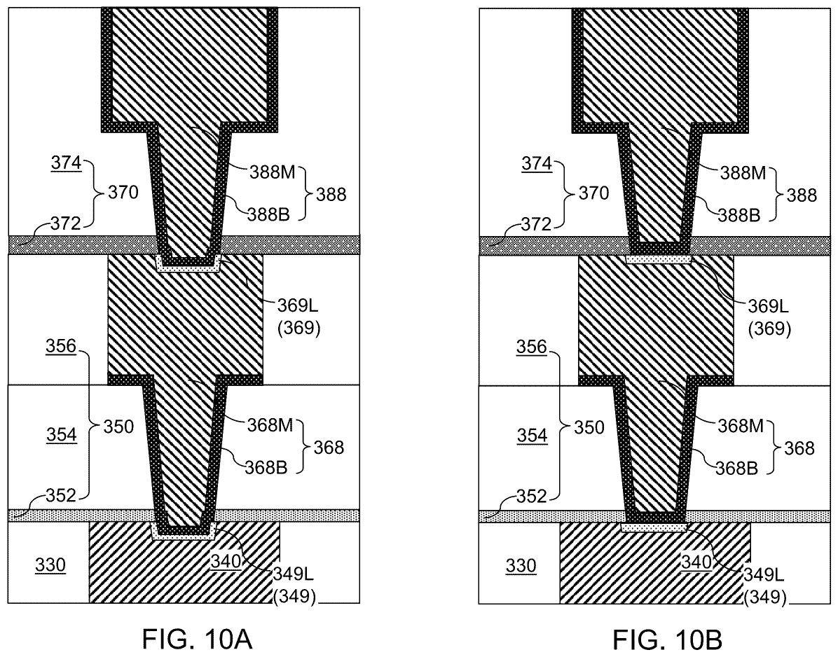

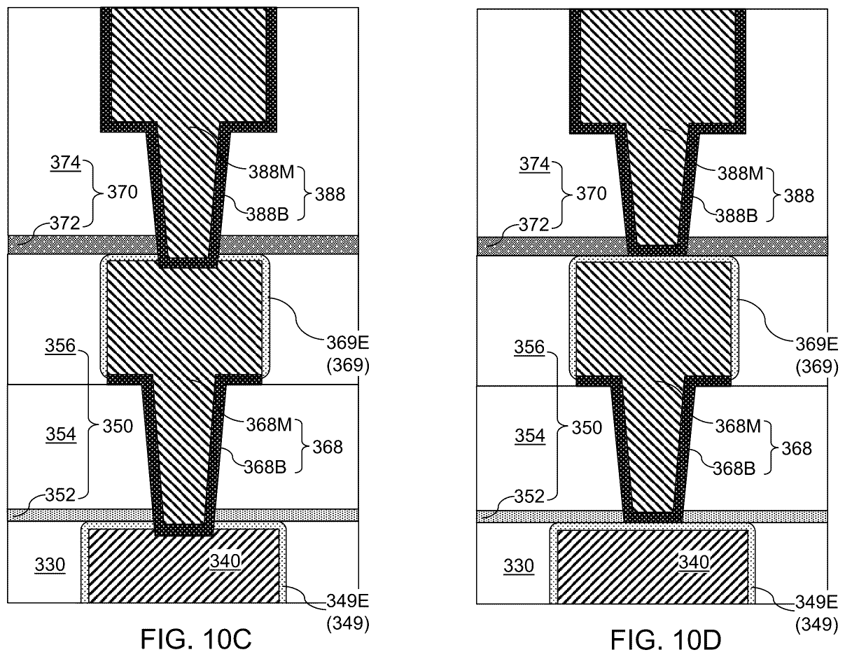

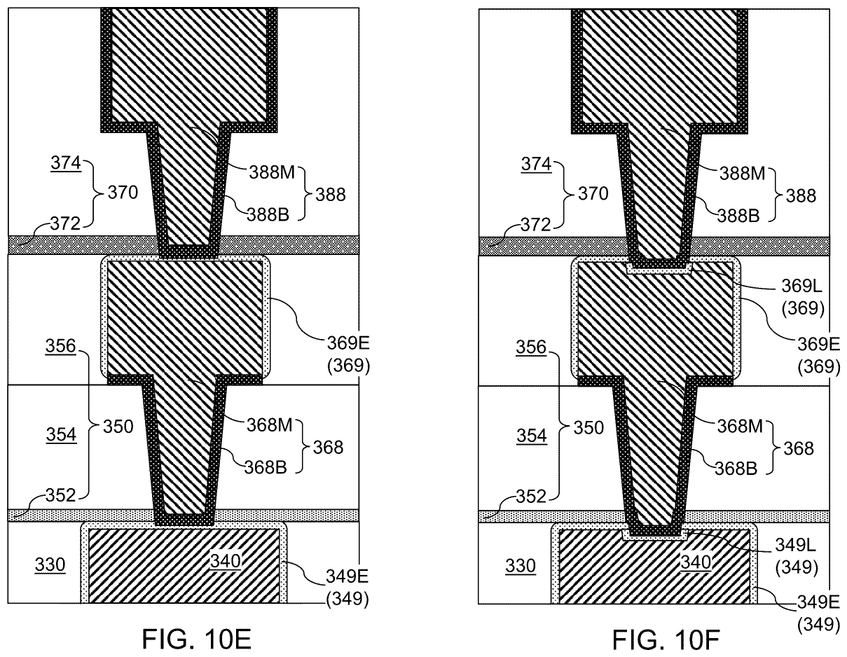

FIGS. 9A and 9B are sequential vertical cross-sectional views of a region of the exemplary structure during formation of copper-containing metal interconnect structures (368, 388) and copper-based tunneling barrier layers 369 according to an eighth embodiment of the present disclosure.

Referring to FIG. 9A, a region of the exemplary structure according to the seventh embodiment is illustrated after formation of an additional copper-based tunneling barrier layer 369. The exemplary structure illustrated in FIG. 9A may be derived from the exemplary structure illustrated in FIG. 6A by converting a surface portion of each first copper-containing metal interconnect structure 368 that underlies a respective cavity 387 and a horizontally-extending thinned portion of the encapsulating copper-based tunneling barrier layer 369E into an additional copper-based tunneling barrier layer 369. The surface portion of each first copper-containing metal interconnect structure 368 is converted into a copper-based dielectric material (such as copper oxide, copper nitride, or copper oxynitride), and incorporates an overlying portion of the encapsulating copper-based tunneling barrier layer 369E to become a localized copper-based tunneling barrier layer 369L. In one embodiment, the thickness of the localized copper-based tunneling barrier layer 369L may be the same as, less than, or greater than, the thickness of the encapsulating copper-based tunneling barrier layer 369E.

In one embodiment, the localized copper-based tunneling barrier layer 369L may have a different material composition than the encapsulating copper-based tunneling barrier layer 369E. In one embodiment, the encapsulating copper-based tunneling barrier layer 369E may be formed by performing an oxidation process and may comprise copper oxide, and the localized copper-based tunneling barrier layer 369L may be formed by performing a nitridation process and may comprise copper nitride or copper oxynitride. In another embodiment, the encapsulating copper-based tunneling barrier layer 369E may be formed by performing a nitridation process and may comprise copper nitride, and the localized copper-based tunneling barrier layer 369L may be formed by performing an oxidation process and may comprise copper oxide or copper oxynitride.

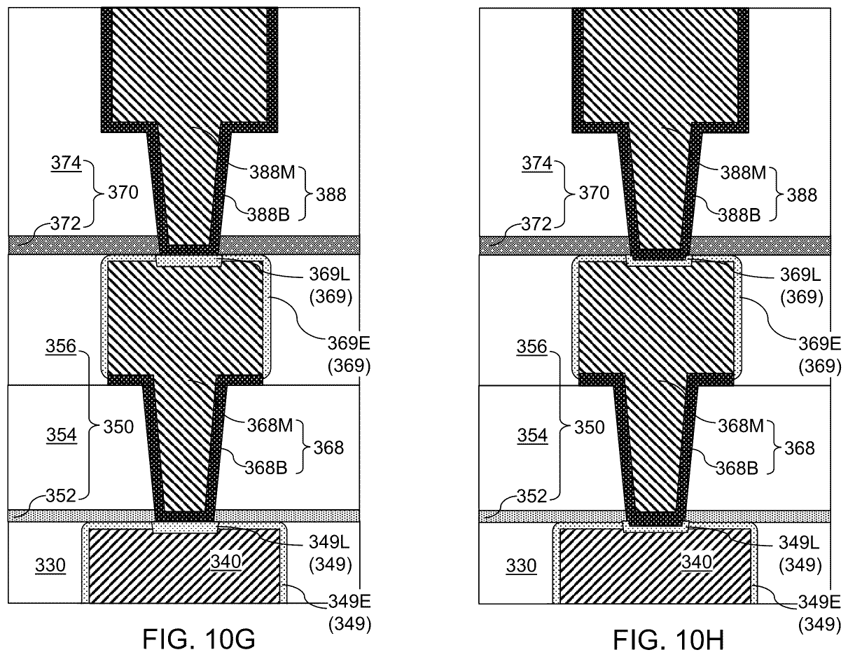

FIGS. 10A-10H are vertical cross-sectional views of a region of the exemplary structure according to additional embodiments of the present disclosure. Generally, the additional embodiments of the present disclosure illustrated in FIGS. 10A-10H may be derived from any of the embodiments described with reference to FIGS. 2A-9B by forming at least one copper-based tunneling barrier layer 349 on a metal interconnect structure 340 that underlies, and is most proximal to, the first copper-containing metal interconnect structure 368. The at least one copper-based tunneling barrier layer 349 may comprise a localized copper-based tunneling barrier layer 349L and/or an encapsulating copper-based tunneling barrier layer 349E. While each of FIGS. 10A-10H illustrates a respective set of at least one copper-based tunneling barrier layer 349 in a specific configuration, it is understood that each configuration for the set of at least one copper-based tunneling barrier layer 349 illustrated in FIGS. 10A-10H may be used in any exemplary structure illustrated in FIGS. 10A-10H . Further, any configuration for the at least one copper-based tunneling barrier layer 369 relative to the first copper-containing metal interconnect structure 368 may be used for the at least one copper-based tunneling barrier layer 349 relative to the metal interconnect structure 340.

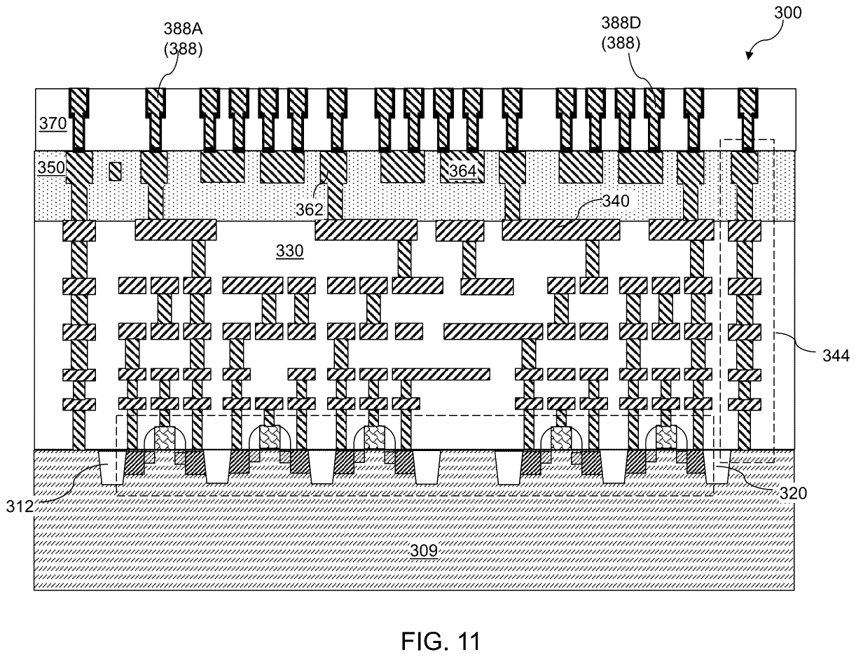

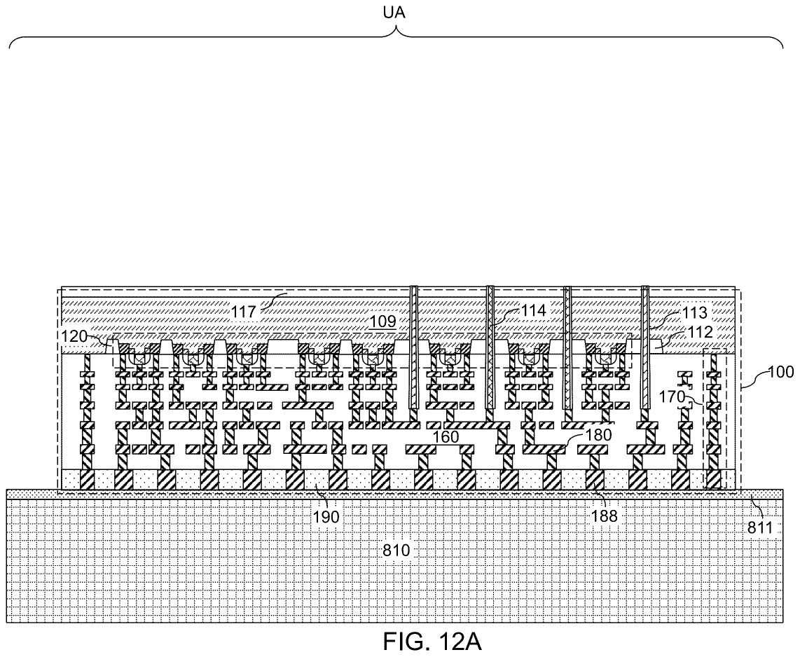

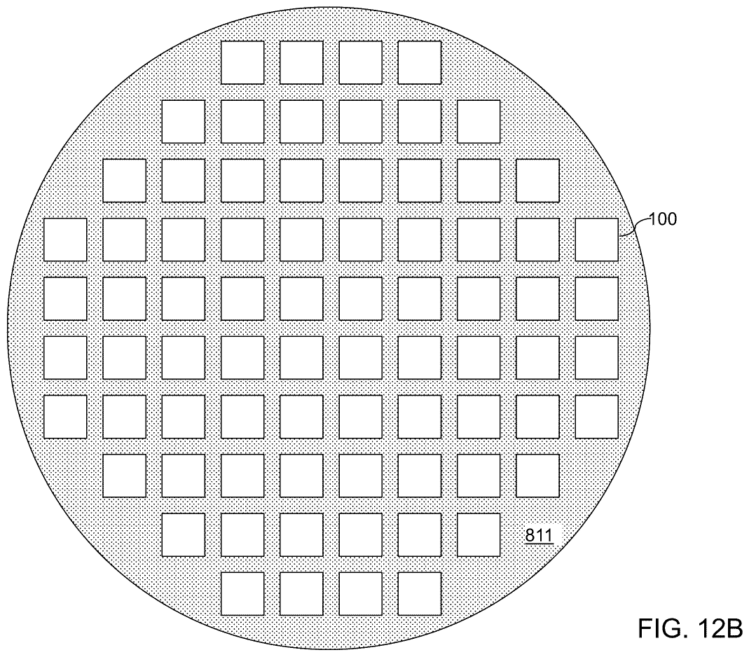

Referring to FIG. 11, the exemplary structure is illustrated after formation of the second copper-containing metal interconnect structures 388. In one embodiment, the second copper-containing metal interconnect structures 388 may comprise active bonding pads 388A that are electrically connected to a respective subset of the metal interconnect structures 340 that is embedded in the interconnect-level dielectric material layers 330. Further, the second copper-containing metal interconnect structures 388 may comprise dummy bonding pads 388D that are electrically isolated from the metal interconnect structures 340. The active bonding pads 388A and the dummy bonding pads 388D are collectively referred to as bonding pads 388. In one embodiment, the semiconductor substrate 309 may be provided as a semiconductor wafer, and a plurality of semiconductor dies 300 may be formed over the semiconductor wafer. In this embodiment, a dicing process may be performed to singulate the plurality of semiconductor dies 300.

Referring to FIGS. 12A and 12B, a reconstituted wafer including a carrier substrate 810 and a two-dimensional array of first semiconductor dies 100 is illustrated. The carrier substrate 810 may be any type of carrier substrate that is suitable for carrying an array of semiconductor dies thereupon. For example, the carrier substrate 810 may be a glass substrate, a semiconductor substrate, or a conductive substrate. The carrier substrate 810 may have a circular shape in a plan view. In other embodiments (not shown), the carrier substrate may have a rectangular shape, or any other shape that is suitable for carrying an array of semiconductor dies thereupon. The first semiconductor dies 100 may be any type of semiconductor dies known in the art. For example, the first semiconductor dies 100 may comprise logic dies including at least one central processing unit (CPU), at least one graphic processing unit (GPU), at least one neural processing unit (NPU), at least one memory array, and/or any other type of semiconductor devices known in the art. The array of the first semiconductor dies 100 may be attached to the carrier substrate 810 using an adhesive layer 811. The array of the first semiconductor dies 100 may be arranged as a periodic two-dimensional array. The area that constitutes a minimum unit of repetition within the periodic two-dimensional array is herein referred to as unit area.

In one embodiment, each first semiconductor die 100 may be attached to the carrier substrate 810 through an adhesive layer 811, which may be a thermally-decomposable adhesive layer such as a polyimide layer, or may be an ultraviolet-decomposable adhesive layer such as an ultraviolet-sensitive tape. The first semiconductor die 100 may comprise a first semiconductor substrate 109, first semiconductor devices 120 located on the first semiconductor substrate 109, first metal interconnect structures 180 formed within first interconnect-level dielectric material layers 160, a first bonding-level dielectric layer 190, and package bonding structures 188 formed within the first bonding-level dielectric layer 190. The package bonding structures 188 function as bonding structures of the composite die to be subsequently formed, and may be configured for solder-mediated bonding (such as chip connection bonding, i.e., microbump bonding, or controlled collapse chip connection bonding, i.e., C4 bonding) or may be configured for metal-to-metal bonding. A first-die edge seal ring structure 170 may vertically extend through the first interconnect-level dielectric material layers 160 and the first bonding-level dielectric layer 190, and may laterally surround the entirety of the first metal interconnect structures 180.

The first semiconductor devices 120 may comprise any semiconductor device known in the art such as field effect transistors and passive devices. First shallow trench isolation structures 112 may be provided within the first semiconductor substrate 109 such that neighboring pairs of first semiconductor devices 120 are electrically isolated from each other. The first semiconductor die 100 may comprise through-substrate via (TSV) structures 114 which vertically extends through the first semiconductor substrate 109 and optionally through a subset of the first interconnect-level dielectric material layers 160. The TSV structures 114 may be electrically isolated from the first semiconductor substrate 109 by dielectric liners 113. A first backside dielectric layer 117 may be provided on the backside of the first semiconductor substrate 109. In this embodiment, the TSV structures 114 may vertically extend through the first backside dielectric layer 117. In one embodiment, the TSV structures 114 may be arranged in a periodic pattern having a same periodicity as the pattern of first active bonding pads to be subsequently formed over the first backside dielectric layer 117. Each of the sidewalls of the first semiconductor die 100 may be physically exposed.

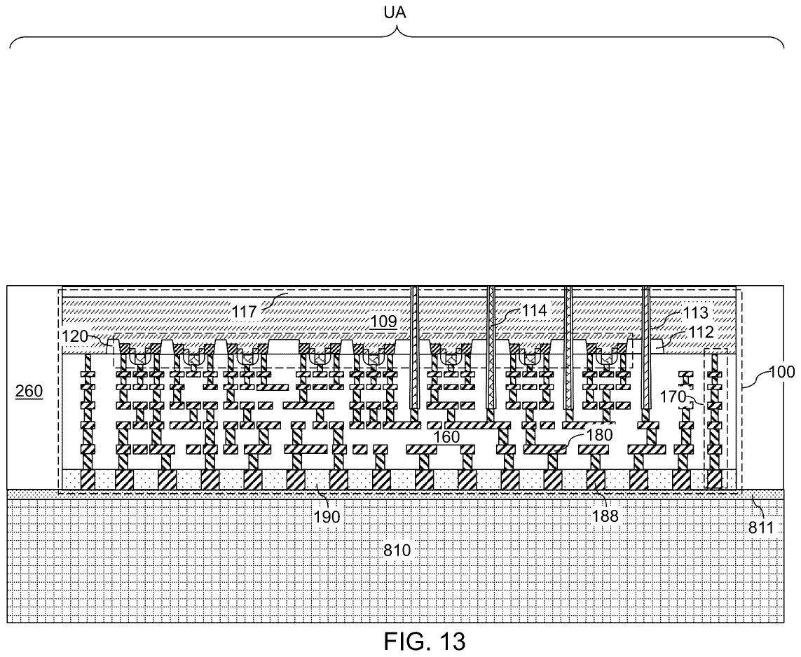

Referring to FIG. 13, a first molding compound may be applied to the gaps between neighboring pairs of the first semiconductor dies 100. The first molding compound may include an epoxy-containing compound that may be hardened (i.e., cured) to provide a dielectric material portion having sufficient stiffness and mechanical strength. The first molding compound may include epoxy resin, hardener, silica (as a filler material), and other additives. The first molding compound may be provided in a liquid form or in a solid form depending on the viscosity and flowability. Liquid first molding compound provides better handling, good flowability, less voids, better fill, and less flow marks. Solid molding compound provides less cure shrinkage, better stand-off, and less die drift. A high filler content (such as 85% in weight) within a molding compound may shorten the time in mold, lower the mold shrinkage, and reduce the mold warpage. Uniform filler size distribution in the molding compound may reduce flow marks, and may enhance flowability. The curing temperature of the molding compound may be lower than the release (debonding) temperature of the adhesive layer 811 in embodiments in which the adhesive layer 811 includes a thermally debonding material. For example, the curing temperature of the first molding compound may be in a range from 125° C. to 150° C.

The first molding compound may be cured at a curing temperature to form a first molding compound matrix 260 that laterally surrounds the two-dimensional array of the first semiconductor dies 100. The first molding compound matrix 260 comprise a plurality of first molding compound die frames that are interconnected to one another. Each first molding compound die frame is a portion of the first molding compound matrix 260 that is located within an area of a repetition unit within a two-dimensional periodic array of structures overlying the carrier substrate 810. Thus, each first molding compound die frame laterally surrounds and embeds a respective first semiconductor die 100.

Portions of the first molding compound matrix 260 that overlie the horizontal plane including the top surfaces of the first semiconductor dies 100 may be removed by a planarization process. For example, the portions of the first molding compound matrix 260 that overlie the horizontal plane may be removed using a chemical mechanical planarization (CMP). The combination of the remaining portion of the first molding compound matrix 260 and the array of first semiconductor dies 100 comprises a reconstituted wafer. Each portion of the first molding compound matrix 260 located within a unit area constitutes a first molding compound die frame. Generally, a first molding compound matrix 260 may be formed around a first semiconductor die 100 such that a top surface of the first molding compound matrix 260 is coplanar with a top dielectric surface of the first semiconductor die 100.

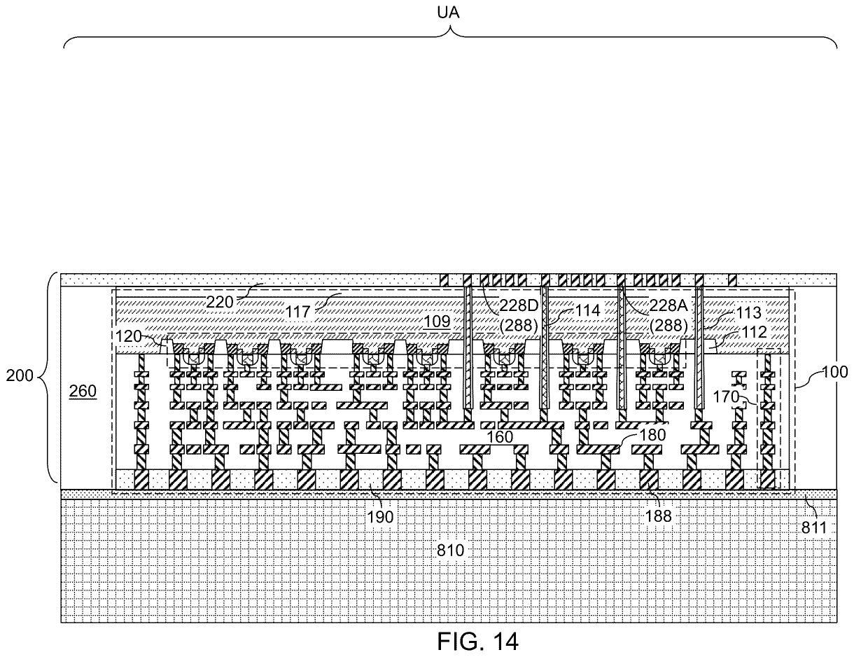

Referring to FIG. 14, a combination of at least one bonding-level dielectric layer 220 and first bonding pads 228 may be formed over the first semiconductor die 100 and the first molding compound matrix 260. The first bonding pads 228 may comprise first active bonding pads 228A that are electrically connected to a respective one of the first metal interconnect structures 180, and may further comprise first dummy bonding pads 228D that are not electrically connected to any other conductive structure. Each of the first active bonding pads 228A may be formed directly on a respective conductive structure (such as a through-substrate via structure 114) within the first semiconductor die 100. Each portion of the exemplary structure within a unit area is herein referred to as a first molded die unit 200, which includes a first die set of a first semiconductor die 100 and portions of the first molding compound matrix 260 and the combination of the at least one bonding-level dielectric layer 220, first active bonding pads 228A, and first dummy bonding pads 228D that are located within a unit area.

Generally, each of the first dummy bonding pads 228D may have the same material composition as, or may have a different material composition than, the first active bonding pads 228A. In one embodiment, all of the first dummy bonding pads 228D may have the same material composition as the first active bonding pads 228A. In another embodiment, all of the first dummy bonding pads 228D may have a different material composition than the first active bonding pads 228A. The at least one bonding-level dielectric layer 220 may comprise a single bonding-level dielectric layer 220, or may comprise a plurality of bonding-level dielectric layers 220.

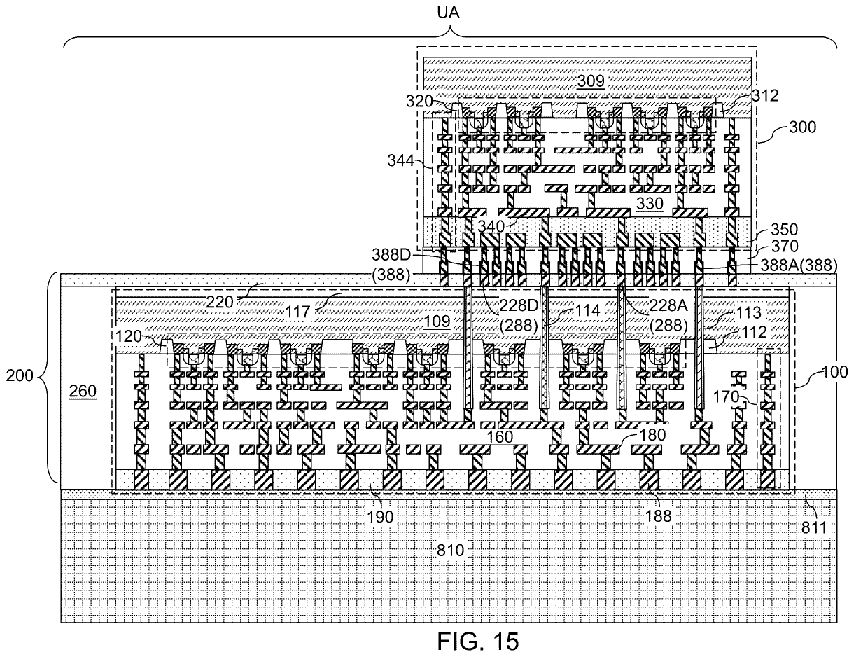

Referring to FIG. 15, second semiconductor dies 300 having second bonding pads (which may comprise second metal interconnect structures 388) may be bonded to a respective one of the first semiconductor dies 100 by metal-to-metal bonding. The second semiconductor die 300 may be the same as the semiconductor die 300 described with reference to FIG. 5 and formed using the processing steps described with reference to FIGS. 1-4F . The bonding pads of the second semiconductor die 300 are hereafter referred to as second bonding pads (which may comprise second metal interconnect structures 388). Generally, each structural element in the second semiconductor die 300 may be hereafter referred to as a second structural element in embodiments in which a similar structural element is present in the first semiconductor dies 100.

A plurality of second semiconductor dies 300 may be bonded to a plurality of first semiconductor dies 100. Each second semiconductor die 300 may be bonded to a respective first semiconductor die 100 by performing a bonding process that bonds the second bonding pads (which may comprise second metal interconnect structures 388) of the second semiconductor die 300 to the first bonding pads 228 within a respective unit area containing the first semiconductor die 100 by metal-to-metal bonding. In one embodiment, the first active bonding pads 228A may be bonded to the second active bonding pads 388A, and the first dummy bonding pads 228D may be bonded to the second dummy bonding pads 388D.

Each second semiconductor die 300 may comprise a second semiconductor substrate 309, second semiconductor devices 320 located on the second semiconductor substrate 309, second metal interconnect structures 340 formed within second interconnect-level dielectric material layers 330, a second dielectric material layer 370, and second bonding pads (which may comprise second metal interconnect structures 388) formed within the second dielectric material layer 370. The second bonding pads (which may comprise second metal interconnect structures 388) may be configured for metal-to-metal bonding such as copper-to-copper bonding. As used herein, metal-to-metal bonding refers to the direct bonding of metal surfaces without the use of intermediate adhesives or solders. Metal-to-metal bonding may be provided through thermocompression bonding and/or diffusion bonding between two metallic surfaces that are in direct contact with each other by performing an anneal process at an elevated temperature.

A second-die edge seal ring structure 344 (which may also be referred to as an edge seal ring structure 344) may vertically extend through the second interconnect-level dielectric material layers 330 and the second dielectric material layer 370, and may laterally surround the entirety of the second metal interconnect structures 340. The second semiconductor devices 320 may comprise any semiconductor device known in the art such as field effect transistors and passive devices. Second shallow trench isolation structures 312 may be provided within the second semiconductor substrate 309 such that neighboring pairs of second semiconductor devices 320 are electrically isolated from each other. All of the sidewalls of the second semiconductor die 300 may be physically exposed.

The second active bonding pads 388A may be bonded to the first active bonding pads 228A through metal-to-metal bonding such as copper to copper bonding. The second dummy bonding pads 388D may be bonded to the first dummy bonding pads 228D through metal-to-metal bonding such as copper to copper bonding. Additionally, a horizontal bottom surface of the second dielectric material layer 370 may be bonded to a topmost surface of the at least one bonding-level dielectric layer 220 by dielectric-to-dielectric bonding such as silicon oxide-to-silicon oxide bonding

In one embodiment, the second semiconductor die 300 comprises an edge seal ring structure 344 that extends continuously along all sidewalls of the second semiconductor die 300. In one embodiment, at least one first dummy bonding pad 228D within the first subset of the first dummy bonding pads 228D overlaps with the edge seal ring structure 344 in the plan view. Additionally or alternatively, at least one first dummy bonding pad 228D within the first subset of the first dummy bonding pads 228D is at least partly within an area enclosed by the edge seal ring structure 344 in the plan view. Additionally or alternatively, at least one first dummy bonding pad 228D within the first subset of the first dummy bonding pads 228D is located at least partly within a frame-shaped area located between an outer periphery of the edge seal ring structure 344 and sidewalls of the second semiconductor die 300 in the plan view.

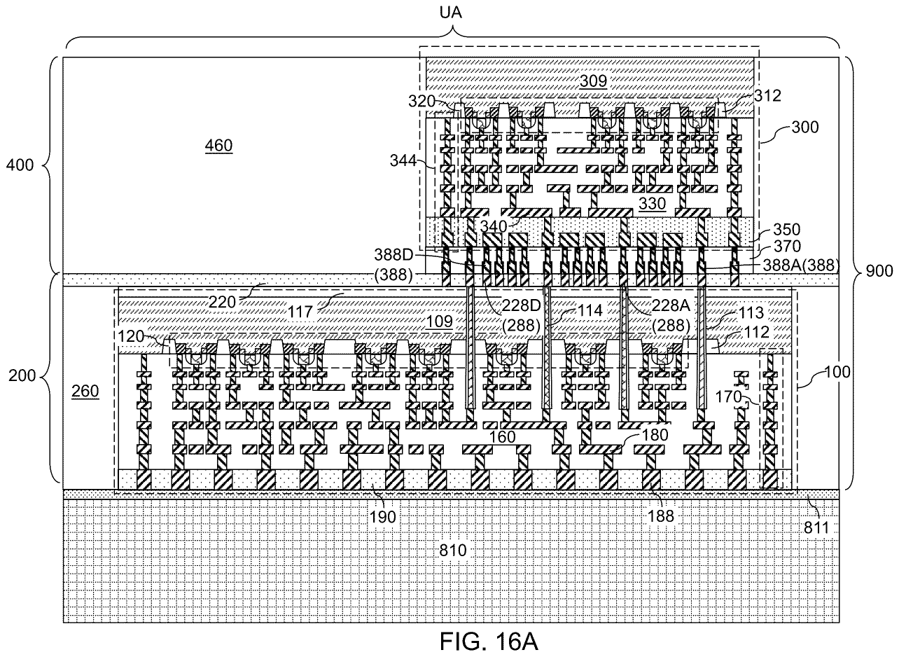

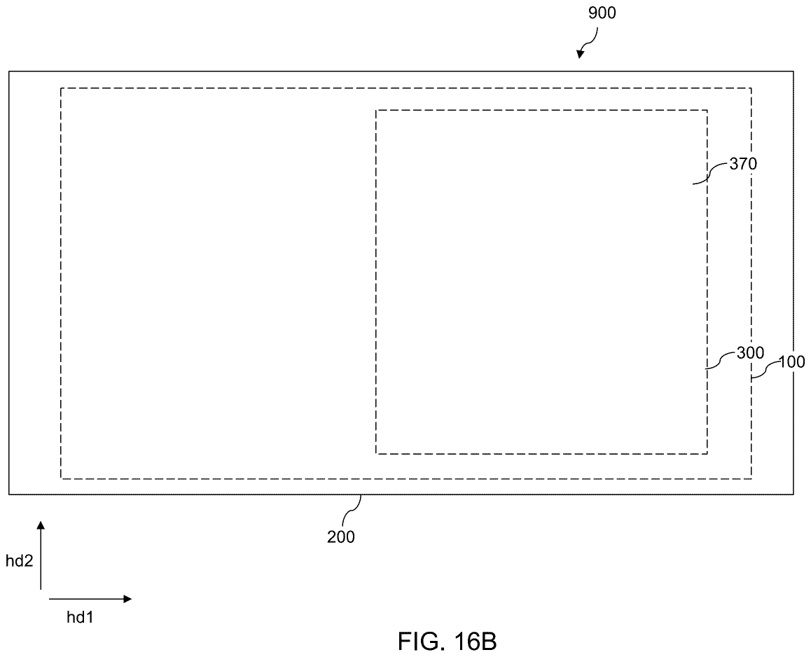

Referring to FIGS. 16A and 16B, a second molding compound matrix 460 may be formed around the second semiconductor dies 300. Specifically, a second molding compound may be applied to the gaps between neighboring pairs of the second semiconductor dies 300. The second molding compound may comprise any material that may be used as the first molding compound. Generally, the second molding compound and the first molding compound may have the same material composition or may have different material compositions. The second molding compound may be cured at a curing temperature to form a second molding compound matrix 460 that laterally surrounds the two-dimensional array of the second semiconductor dies 300. The second molding compound matrix 460 comprises a plurality of second molding compound die frames that are interconnected to one another. Each second molding compound die frame is a portion of the second molding compound matrix 460 that is located within an area of a repetition unit within a two-dimensional periodic array of structures overlying the carrier substrate 810. Thus, each second molding compound die frame laterally surrounds and embeds a respective second semiconductor die 300.

Portions of the second molding compound matrix 460 that overlie the horizontal plane including the top surfaces of the second semiconductor dies 300 may be removed by a planarization process. For example, the portions of the second molding compound matrix 460 that overlies the horizontal plane may be removed using a chemical mechanical planarization (CMP). The combination of the remaining portion of the second molding compound matrix 460 and the array of second semiconductor dies 300 comprises second molded die units 400. Each second molded die unit 400 comprises a second semiconductor die 300 and a portion of the second molding compound matrix 460 located within a unit area. Each portion of the second molding compound matrix 460 located within a unit area constitutes a second molding compound die frame. Generally, a second molding compound matrix 460 may be formed around a second semiconductor die 300 such that a top surface of the second molding compound matrix 460 is coplanar with a top surface of the second semiconductor die 300. Each vertical stack of a first molded die unit 200 and a second molded die unit 400 constitutes a composite die 900. A two-dimensional array of composite dies 900 may be formed over the carrier substrate 810.

Subsequently, the carrier substrate 810 may be detached from a reconstituted wafer including a two-dimensional array of composite dies 900 by decomposing the adhesive layer 811. A thermal anneal process or an ultraviolet irradiation process may be used to decompose the adhesive layer 811. A suitable clean process may be performed to clean the physically exposed surfaces of the first bonding-level dielectric layer 190 and the package bonding structures 188.

The reconstituted wafer may be diced along dicing channels to singulate the composite dies 900. Each composite die 900 comprises an assembly of a first semiconductor die 100; a first molding compound matrix 260 (which is a first molding compound die frame); a combination of at least one bonding-level dielectric layer 220, first active bonding pads 228A, and first dummy bonding pads 228D; a second semiconductor die 300 including second bonding pads (which may comprise second metal interconnect structures 388) that are bonded to the first active bonding pads 228A via metal-to-metal bonding; and a second molding compound matrix 460 (which is a second molding compound die frame). In one embodiment, each composite die 900 may have a pair of first sidewalls that are parallel to a first horizontal direction hd1 and a pair of second sidewalls that are parallel to a second horizontal direction hd2 that is perpendicular to the first horizontal direction hd1.

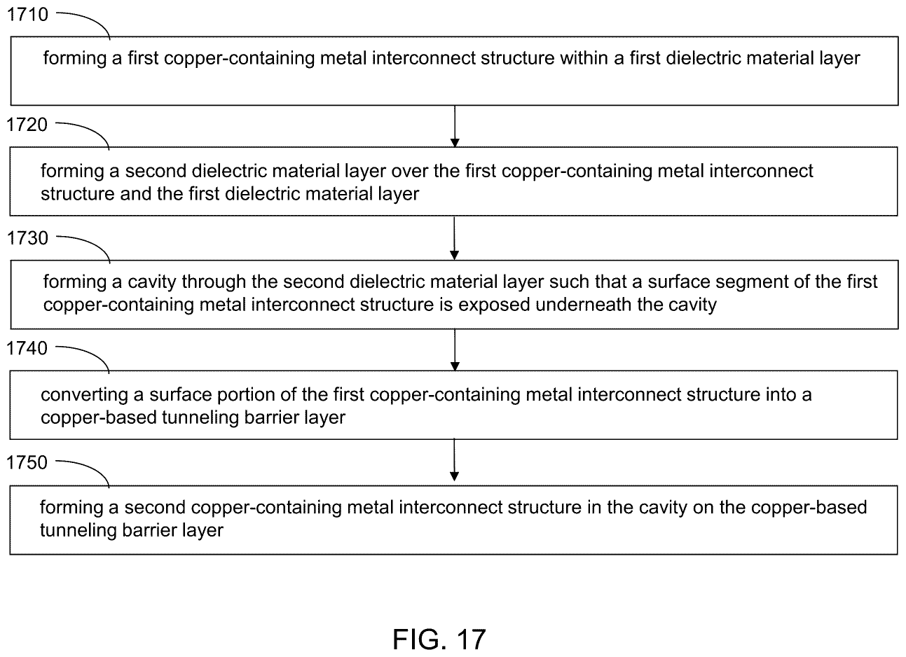

Referring to FIG. 17, a first flowchart is illustrated, which illustrates steps for forming a device structure according to an embodiment of the present disclosure.

Referring to step 1710 and FIGS. 1, 2A-2G, 3A, 10A, 10B, and 10F-10H, a first copper-containing metal interconnect structure 368 within a first dielectric material layer 350 is formed.

Referring to step 1720 and FIGS. 2H, 2I, 3A, 10A, 10B, and 10F-10H, a second dielectric material layer 370 may be formed over the first copper-containing metal interconnect structure 368 and the first dielectric material layer 350.

Referring to step 1730 and FIGS. 2J, 3B, 10A, 10B, and 10F-10H, a cavity 387 may be formed through the second dielectric material layer 370 such that a surface segment of the first copper-containing metal interconnect structure 368 is exposed underneath the cavity 387.

Referring to step 1740 and FIGS. 2K, 3C, 10A, 10B, and 10F-10H, a surface portion of the first copper-containing metal interconnect structure 368 may be converted into a copper-based tunneling barrier layer 369.

Referring to step 1750 and FIGS. 2L, 3D, 10A, 10B, and 10F-10H, a second copper-containing metal interconnect structure 388 may be formed in the cavity 387 on the copper-based tunneling barrier layer 369.

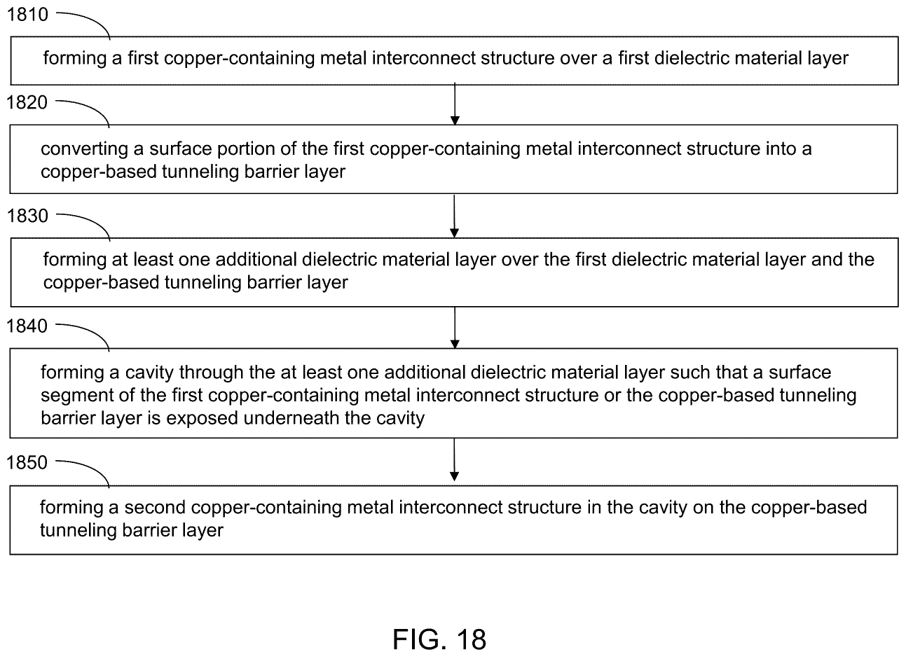

Referring to FIG. 18, a second flowchart is illustrated, which illustrates steps for forming a device structure according to an embodiment of the present disclosure.

Referring to step 1810 and FIGS. 1, 4A, 5A, 6A, 7A, 8A, 9A, and 10C-10H, a first copper-containing metal interconnect structure 368 may be formed over a first dielectric material layer such as a combination of an optional first capping passivation layer 352 and a first via-level dielectric layer 354.

Referring to step 1820 and FIGS. 4B, 5A, 6A, 7A, 8A, 9A, and 10C-10H, a surface portion of the first copper-containing metal interconnect structure 368 may be converted into a copper-based tunneling barrier layer 369.

Referring to step 1830 and FIGS. 4C, 4D, 5A, 6A, 7A, 8A, 9A, and 10C-10H, at least one additional dielectric material layer (356, 370) may be formed over the first dielectric material layer (352, 354) and the copper-based tunneling barrier layer 369.

Referring to step 1840 and FIGS. 4E, 5A, 6A, 7A, 8A, 9A, and 10C-10H, a cavity 387 may be formed through the at least one additional dielectric material layer (356, 370) such that a surface segment of the first copper-containing metal interconnect structure 368 or the copper-based tunneling barrier layer 369 is exposed underneath the cavity 387.

Referring to step 1850 and FIGS. 4F, 5B, 6B, 7B, 8B, 9B, and 10C-10H, a second copper-containing metal interconnect structure 388 may be formed in the cavity 387 on the copper-based tunneling barrier layer 369.

Referring to all drawings and according to various embodiments of the present disclosure, a device structure is provided, which comprises: a first copper-containing metal interconnect structure 368 formed within a first dielectric material layer 350; a copper-based tunneling barrier layer 369 located on a surface of the first copper-containing metal interconnect structure 368; and a second copper-containing metal interconnect structure 388 embedded in a second dielectric material layer 370 that overlies the first dielectric material layer 350, wherein the second copper-containing metal interconnect structure 388 is in direct contact with the copper-based tunneling barrier layer 369.

In one embodiment, the copper-based tunneling barrier layer 369 has a thickness in a range from 0.5 nm to 2.0 nm. In one embodiment, the copper-based tunneling barrier layer 369 contacts sidewalls of the first copper-containing metal interconnect structure 368. In one embodiment, a first portion of the copper-based tunneling barrier layer 369 that is interposed between the first copper-containing metal interconnect structure 368 and the second copper-containing metal interconnect structure 388 has a lesser thickness than a second portion of the copper-based tunneling barrier layer 369 that contacts the first copper-containing metal interconnect structure 368 and does not contact the second copper-containing metal interconnect structure 388. In one embodiment, the device structure comprises an additional copper-based tunneling barrier layer 369 in contact with a top surface and a sidewall of the first copper-containing metal interconnect structure 368. In one embodiment, the copper-based tunneling barrier layer 369 comprises an inhomogeneous copper oxynitride material such that a nitrogen concentration gradient and an oxygen concentration gradient is present in the copper-based tunneling barrier layer 369.

Generally, copper atoms within a copper-containing metal interconnect structure may diffuse along grain boundaries, particularly under conditions of elevated temperature and compressive stress. This diffusion is driven by a stress gradient, which causes copper atoms to migrate into regions of lower stress, often accumulating at the peripheries of grain boundaries. Over time, this accumulation may lead to the formation of protrusions known as hillocks on the surface of the copper interconnect structure. Hillocks are particularly problematic as they may cause physical disruptions in the interconnect layers, leading to failures in the semiconductor device.

In the presence of hydrogen or nitrogen radicals, which may be introduced during various processing steps such as plasma treatments, these radicals may further influence the diffusion process. Hydrogen radicals may penetrate the grain boundaries, interacting with the copper atoms and possibly facilitating their migration by weakening the atomic bonds within the copper structure. Similarly, nitrogen radicals or trapped nitrogen atoms could either enhance or hinder diffusion depending on their interaction with the copper atoms and the resulting changes in the local stress environment. These radicals might also become trapped within the grain boundaries, altering the microstructure and potentially affecting the formation and growth of hillocks. The presence of these radicals or trapped atoms may therefore play a role in the reliability and stability of copper interconnect structures, especially under conditions that promote hillock formation.

Embodiments of the present disclosure suppress diffusion of copper atoms along grain boundaries and the subsequent formation of hillocks under compressive stress and elevated temperatures. By incorporating a copper-based tunneling barrier layer 369 into the device structure, the methods mitigate the diffusion of copper atoms to the surface, thereby reducing the risk of hillock formation. This tunneling barrier layer, which may be composed of copper oxide, copper nitride, or copper oxynitride, is strategically formed on the surface of the first copper-containing metal interconnect structure 368, creating a physical barrier that impedes the migration of copper atoms along grain boundaries.

The copper-based tunneling barrier layer 369 is formed by exposing the surface portion of the first copper-containing metal interconnect structure 368 to an ambient including an oxidizer or nitridation agent gas at a controlled temperature. This process results in the formation of a thin, uniform layer that is both electrically conductive and resistant to atom migration. The barrier layer's role is twofold: it allows for electron tunneling between the first and second copper-containing metal interconnect structures (368, 388) while simultaneously acting as a buffer that absorbs and redistributes stress. This prevents the concentration of stress at the copper-dielectric interface, which is a primary factor in hillock formation. Additionally, by controlling the thickness of the copper-based tunneling barrier layer 369 (typically in the range of 0.5 nm to 2.0 nm), the methods ensure that the layer is effective in blocking copper diffusion without compromising the electrical connectivity required for the device's functionality.

According to an aspect of the present disclosure, the tunneling barrier layer may be formed through various processes, including thermal oxidation, thermal nitridation, plasma oxidation, and plasma nitridation. The choice of process and materials may be tailored to optimize the barrier's performance under specific operating conditions. For instance, the use of plasma treatments may introduce hydrogen or nitrogen radicals that become trapped within the grain boundaries, further stabilizing the copper structure and preventing unwanted diffusion. This added stability is particularly advantageous in high-temperature environments where conventional copper interconnects might otherwise fail due to hillock formation and delamination.

By integrating the copper-based tunneling barrier layer 369 into the interconnect structure, embodiments of the present disclosure provide a robust solution to the problem of stress-induced reliability issues in copper interconnects. The barrier layer not only reduces the likelihood of hillock formation by inhibiting copper atom migration but also enhances the overall durability and longevity of the device structure. The structures and the methods of the present disclosure support the continued use of copper in advanced semiconductor devices, particularly as designs become more complex and densely packed, by ensuring that the interconnects remain reliable even under challenging thermal and mechanical conditions.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming a first copper-containing metal interconnect structure within a first dielectric material layer;
forming a second dielectric material layer over the first copper-containing metal interconnect structure and the first dielectric material layer;
forming a cavity through the second dielectric material layer such that a surface segment of the first copper-containing metal interconnect structure is exposed underneath the cavity;
converting a surface portion of the first copper-containing metal interconnect structure into a copper-based tunneling barrier layer; and
forming a second copper-containing metal interconnect structure in the cavity on the copper-based tunneling barrier layer.

2. The method of claim 1, wherein the copper-based tunneling barrier layer comprises a dielectric material selected from copper oxide, copper nitride, or copper oxynitride.

3. The method of claim 1, wherein the copper-based tunneling barrier layer is formed by exposing the surface portion of the first copper-containing metal interconnect structure to an ambient including an oxidizer gas or a nitridation agent gas at a temperature in a range from 10 degrees Celsius to 450 degrees Celsius.

4. The method of claim 3, wherein the ambient comprises at least one of ammonia gas, oxygen gas, ozone gas, nitrous oxide (N₂O) gas, nitric oxide (NO) gas, and nitrogen dioxide (NO₂) gas.

5. The method of claim 1, wherein the copper-based tunneling barrier layer is formed by performing at least one of a thermal oxidation process and a thermal nitridation process.

6. The method of claim 1, wherein the copper-based tunneling barrier layer is formed by performing at least one of a plasma oxidation process and a plasma nitridation process.

7. The method of claim 1, wherein the copper-based tunneling barrier layer is formed by a combination of an oxidation process and a nitridation process such that a nitrogen concentration gradient and an oxygen concentration gradient is present in the copper-based tunneling barrier layer.

8. The method of claim 1, further comprising vertically recessing a portion of a top surface of the first copper-containing metal interconnect structure during formation of the cavity, wherein physically exposed surfaces of the first copper-containing metal interconnect structure comprise a recessed surface segment of the first copper-containing metal interconnect structure and at least one sidewall surface segment of the first copper-containing metal interconnect structure, and wherein a periphery of the recessed surface segment coincides with a bottom periphery of the at least one sidewall surface segment.

9. A method of forming a device structure, comprising:
forming a first copper-containing metal interconnect structure over a first dielectric material layer;
converting a surface portion of the first copper-containing metal interconnect structure into a copper-based tunneling barrier layer;
forming at least one additional dielectric material layer over the first dielectric material layer and the copper-based tunneling barrier layer;
forming a cavity through the at least one additional dielectric material layer such that a surface segment of the first copper-containing metal interconnect structure or the copper-based tunneling barrier layer is exposed underneath the cavity; and
forming a second copper-containing metal interconnect structure in the cavity on the copper-based tunneling barrier layer.

10. The method of claim 9, wherein the copper-based tunneling barrier layer is formed by performing at least one of a surface oxidation process and a surface nitridation process.

11. The method of claim 9, further comprising removing a portion of the copper-based tunneling barrier layer from underneath the cavity.

12. The method of claim 9, wherein the copper-based tunneling barrier layer is formed on a top surface and at least one sidewall of the first copper-containing metal interconnect structure.

13. The method of claim 9, wherein:
a horizontally-extending portion of the copper-based tunneling barrier layer is interposed between the first copper-containing metal interconnect structure and the cavity upon formation of the cavity; and
the second copper-containing metal interconnect structure is formed on the horizontally-extending portion of the copper-based tunneling barrier layer.

14. The method of claim 9, further comprising converting a proximal portion of the first copper-containing metal interconnect structure underlying the cavity into an additional copper-based tunneling barrier layer, wherein the second copper-containing metal interconnect structure is formed on the additional copper-based tunneling barrier layer.

15. A device structure comprising:
a first copper-containing metal interconnect structure formed within a first dielectric material layer;
a copper-based tunneling barrier layer located on a surface of the first copper-containing metal interconnect structure; and
a second copper-containing metal interconnect structure embedded in a second dielectric material layer that overlies the first dielectric material layer, wherein the second copper-containing metal interconnect structure is in direct contact with the copper-based tunneling barrier layer.

16. The device structure of claim 15, wherein the copper-based tunneling barrier layer has a thickness in a range from 0.5 nm to 2.0 nm.

17. The device structure of claim 15, wherein the copper-based tunneling barrier layer contacts sidewalls of the first copper-containing metal interconnect structure.

18. The device structure of claim 15, wherein a first portion of the copper-based tunneling barrier layer that is interposed between the first copper-containing metal interconnect structure and the second copper-containing metal interconnect structure has a lesser thickness than a second portion of the copper-based tunneling barrier layer that contacts the first copper-containing metal interconnect structure and not contacting the second copper-containing metal interconnect structure.

19. The device structure of claim 15, further comprising an additional copper-based tunneling barrier layer in contact with a top surface and a sidewall of the first copper-containing metal interconnect structure.

20. The device structure of claim 15, wherein the copper-based tunneling barrier layer comprises an inhomogeneous copper oxynitride material such that a nitrogen concentration gradient and an oxygen concentration gradient is present in the copper-based tunneling barrier layer.
